(19) United States
(12) Patent Application Publication
(10) Pub. No.: US 2025/0343025 A1
(43) Pub. Date: Nov. 6, 2025

(54) MULTI-BEAM PARTICLE MICROSCOPE WITH IMPROVED MULTI-BEAM GENERATOR FOR FIELD CURVATURE CORRECTION AND MULTI-BEAM GENERATOR

(71) Applicant: Carl Zeiss MultiSEM GmbH, Oberkochen (DE)

(72) Inventors: Dirk ZEIDLER, Oberkochen (DE); Thomas SCHMID, Aalen (DE); Daniel WEISS, Essingen-Forst (DE); Felix MENKE, Oberkochen (DE); Christian VEIT, Leinfelden-Echterdingen (DE); Benedikt TRATZMILLER, Stuttgart (DE); Thomas DIETERLE, Murrhardt (DE); Walter PAULS, Huettlingen (DE); Ulrich BIHR, Dirgenheim (DE); Sandra VOGEL, Ulm (DE)

(21) Appl. No.: 19/269,782

(22) Filed: Jul. 15, 2025

Related U.S. Application Data
(63) Continuation of application No. PCT/EP2024/025014, filed on Jan. 10, 2024.

(30) Foreign Application Priority Data
Jan. 25, 2023 (DE) 10 2023 101 781.0

(51) Int. Cl. H01J 37/26; H01J 37/12; H01J 37/141; H01J 37/248

(52) U.S. Cl. CPC H01J 37/26; H01J 37/12; H01J 37/141; H01J 37/248; H01J 2237/04; H01J 2237/1202

(57) ABSTRACT

A multi-beam generator for a charged-particle multi-beam system comprises: a stack of multi-aperture plates with at least a first multi-lens array for long range focal length variation; and a second multi-lens array for short range focal length variation. Aperture diameters of the first multi-lens array vary to encode a pre-compensation of a spherically curved image field in an object plane of the multi-beam system. Aperture diameters of the second multi-lens array vary to encode a pre-compensation of a residual image field error in the object plane which is not pre-compensated by the first multi-lens array. The control unit of the multi-beam generator provides driving voltages to the first and second lens arrays based on the current working point of the charged-particle multi-beam system.

### CROSS-REFERENCE TO RELATED APPLICATIONS

The present application is a continuation of, and claims benefit under 35 USC 120 to, international application No. PCT/EP2024/025014, filed Jan. 10, 2024, which claims benefit under 35 USC 119 of German Application No. 10 2023 101 781.0, filed Jan. 25, 2023. The entire disclosure of each of these applications is incorporated by reference herein.

### FIELD

In general, the disclosure relates to multi-beam particle microscopes which operate using a plurality of individual particle beams. For example, the disclosure relates to a multi-beam particle microscope with an improved multi-beam generator for field curvature correction.

### BACKGROUND

With the continuous development of ever smaller and ever more complex microstructures such as semiconductor components, there is a desire to develop and optimize planar production techniques and inspection systems for producing and inspecting small dimensions of the microstructures. By way of example, the development and production of the semiconductor components involves monitoring of the design of test wafers, and the planar production techniques involve a process optimization for a reliable production with a high throughput. Moreover, there have been recent demands for an analysis of semiconductor wafers for reverse engineering and for a customer-specific, individual configuration of semiconductor components. Therefore, there is a desire for an inspection system which can be used with a high throughput for examining the microstructures on wafers with a great accuracy.

Typical silicon wafers used in the production of semiconductor components have diameters of up to 300 mm. Each wafer is usually subdivided into 30 to 60 repeating regions (“dies”) with a size of up to 800 mm². A semiconductor apparatus comprises a plurality of semiconductor structures, which are produced in layers on a surface of the wafer by planar integration techniques. Semiconductor wafers typically have a plane surface on account of the production processes. The structure sizes of the integrated semiconductor structures in this case extend from a few μm to a few nm, wherein the structure dimensions are expected to become even smaller in the near future. In the future, structure sizes or critical dimensions (CD) are expected to accommodate the 3 nm, 2 nm or even smaller technology nodes of the International Technology Roadmap for Semiconductors. In the case of the aforementioned small structure sizes, defects of the size of the critical dimensions are to be identified quickly in a very large area. For several applications, the desired accuracy of a measurement provided by an inspection device is even higher, for example by a factor of two or one order of magnitude. By way of example, a width of a semiconductor feature would be measured with an accuracy of below 1 nm, for example 0.3 nm or even less, and a relative position of semiconductor structures would be determined with a superposition accuracy of below 1 nm, for example 0.3 nm or even less.

The MSEM, a multi-beam scanning electron microscope, is a relatively new development in the field of charged particle systems (charged particle microscopes, CPMs). By way of example, a multi-beam scanning electron microscope is disclosed in U.S. Pat. No. 7,244,949 B2 and in US 2019/0355544 A1. In the case of a multi-beam electron microscope or MSEM, a sample is irradiated simultaneously with a plurality of individual electron beams, which are arranged in a field or raster. By way of example, 4 to 10,000 individual electron beams can be provided as primary radiation, with each individual electron beam being separated from an adjacent individual electron beam by a pitch of 1 to 200 micrometers. By way of example, an MSEM has approximately 100 separated individual electron beams (“beamlets”), which for example are arranged in a hexagonal raster, with the individual electron beams being separated by a distance of approximately 10 μm. The plurality of charged individual particle beams (primary beams) are typically focused, individually in each case, on a surface of a sample to be examined by way of common large-field optics including, inter alia, a common objective lens. By way of example, the sample can be a semiconductor wafer which is fastened to a wafer holder that is assembled on a movable stage. During the illumination of the wafer surface with the charged primary individual particle beams, interaction products, for example secondary electrons or backscattered electrons, can emanate from the surface of the wafer. Their respective start points typically correspond to those locations on the sample on which the plurality of primary individual particle beams are focused in each case. The amount and the energy of the interaction products depends inter alia on the material composition and the topography of the wafer surface. The interaction products can form a plurality of secondary individual particle beams (secondary beams), which are collected by the common objective lens and which are incident on a detector arranged in a detection plane as a result of a projection imaging system of the multi-beam inspection system. The detector can comprise a plurality of detection regions, each of which comprises a plurality of detection pixels, and the detector captures an intensity distribution for each of the secondary individual particle beams. An image field of for example 100 μm×100 μm can be obtained in the process.

A known multi-beam electron microscope can comprise a sequence of electrostatic and magnetic elements. At least some of the electrostatic and magnetic elements can be adjustable in order to adapt the focus position and the stigmation of the plurality of charged individual particle beams. Such a multi-beam system with charged particles can further comprise at least one cross-over plane of the primary or the secondary charged individual particle beams. Moreover, such a system can comprise detection systems to make the adjustment easier. Such a multi-beam particle microscope can comprise at least one beam deflector (“deflection scanner”) for collective scanning of a region of the sample surface via the plurality of primary individual beams in order to obtain an image field of the sample surface.

In general, as the desired imaging quality properties increase, so do the demands on the desired properties on the multi-beam particle microscope used for imaging. For a very good resolution of a multi-beam particle microscope, for example, a field curvature, i.e. the variation of focal length, is desirably minimized. As a first measure, the electron optics or charged particle optics of the multi-beam particle microscope can be optimized. However, these measures typically have a limit due to Scherzer's theorem. This limit is generally not sufficient for current desired beam uniformity.

Therefore, it has been suggested to apply active devices for individual focal length adjustment per beam, applying, for example, arrays of individually addressable ring-electrodes as active parts of micro-Einzel lens arrays. A focal length of an individual micro-Einzel lens is approximately in quadratic dependency from the voltage applied to the individual lens electrode. However, these devices for per-beam-correction of field curvature can be difficult to produce and expensive. It is generally desirable then that every single micro-correction device functions perfectly; otherwise, in general, this kind of correction device not useful. Furthermore, it is for example challenging to provide every micro-Einzel lens array with a voltage in the order of more than 50V, more than 100V or even more than 400V. Then, considerable insulation issues can arise and current devices might have only a very limited lifetime. Examples for active correction devices can, for example, be found in U.S. Pat. Nos. 5,834,783, 6,483,120, 6,903,353, 7,126,141 and 11,145,485.

An alternative approach has suggested using passive devices, for example arrays of Einzel lens systems which are monolithic, with only one driving voltage provided for the entire array. It is known that the focal length of an Einzel lens is approximately proportional to the diameter of the aperture of the middle electrode of the Einzel lens. Therefore, by appropriately varying the diameters of the apertures in a multi-aperture plate forming part of the Einzel lens array, an individual focal length variation per beam can also be achieved. Thus, by providing only one driving voltage to the multi-aperture plate with varying hole diameters, field curvature and also an image field inclination can be corrected. Examples for such passive correction devices can, for example, be found in JP60105229, U.S. patent. Nos. 10,504,681, 10,784,070 and 11,139,138. Further examples are disclosed in U.S. Pat. No. 10,923,313 B1 and U.S. Pat. No. 11,322,335 B2.

However, a variation of the aperture diameters in the described passive correction devices is practically limited, since an aperture diameter can never be bigger than the beam pitch between neighbouring individual particle beams and it is not smaller than a diameter of an individual particle beam. Furthermore, the voltages applied to the monolithic multi-aperture plates with varying aperture diameters generally cannot be increased arbitrarily without considerable insulation and short-circuiting issues.

WO 2007/028595 A2 discloses a particle optical component with two subsequently arranged multi-aperture plates which are shaped in such a way that a gap between the two plates shows a radial dependency. A variable potential is provided to each of the two plates resulting in an electric field of varying strength within the gap between the two multi-aperture plates which can be used to contribute to a field curvature correction. Further correction can be achieved in combination with a single aperture plate arranged downstream of the two multi-aperture plates.

In practice, further challenges can occur. Because modern multi-beam particle microscopes work with ever more individual particle beams, the size of the image field ever increases. A bigger image field naturally has an ever bigger focal length variation within the image field. Additionally, it is a general demand that multi-beam particle microscopes and systems work at different working points resulting in different field curvatures that are corrected each in a highly precise manner. However, according to certain known systems, only a quasi-static field curvature is corrected.

### SUMMARY

The present disclosure seeks to provide improvements. For example, the present disclosure seeks to provide a highly precise field curvature correction for multi-beam particle microscopes working with a high number of individual particle beams and having thus large image fields.

The present disclosure seeks to allow for a dynamic field curvature correction of multi-beam particle microscopes operating at different working points.

The present disclosure seeks to provide a multi-beam particle microscope allowing for a big field curvature correction as such. Furthermore, tuning of the field curvature correction shall be possible within a big range.

A very general finding of the present disclosure is that using hybrid concepts combining several methods can be beneficial.

An aspect of the disclosure is the analysis of an error that is made when carrying out field curvature correction at different working points of a multi-beam particle microscope. A change of working point, such as a change of the beam pitch, the magnification, the landing energy, the working distance etc., can lead to changes of the refractive power of the particle optical lenses. Changes of the refractive power can result in the generation of different field curvatures in the object plane. The image field curvature is mathematically a sphere which means that it has a radius, hence it is also labelled image shell.

The inventors have analyzed the errors occurring according to the passive concepts applying Einzel-lens systems with varying aperture diameters when trying to correct different image field curvatures. If the image curvature is tuned by varying the driving voltage applied to the middle electrode of the micro-Einzel lens array, the difference in the focal length variation is linear for all individual particle beams. On the other hand, there is mathematically no linear scaling when trying to scale a first sphere with a first radius (corresponding to a first image field curvature) into a second sphere with a second radius (corresponding to a second image field curvature). Thus, a solely linear scaling by simply tuning the applied voltage can lead to an imperfect field curvature correction. In other words, any linear scaling of a spherical field curvature does not result in a bigger or smaller sphere, but in a “compressed” or “elongated” “sphere” which is strictly speaking no sphere anymore.

However, the error that is made by compressing or elongating the image sphere has a certain mathematical characteristic which is specific for the particle optical system. The error is normally of third order and can for example be well approximated by a polynomial of 4^{th} degree.

The present disclosure takes a new two-step approach. First, a long range focal length variation is carried out using a micro-Einzel lens array with a plurality of apertures with variable diameters at a selected working point. Second, the specific error made in the long range focal length variation is specifically corrected by a subsequent short range focal length variation. This error correction can either be encoded in a second micro-Einzel lens array with a plurality of apertures with an error specific variation of the aperture diameters or by an active correction device using for example individually adjustable ring electrodes.

According to a first aspect, the disclosure relates to a multi-beam charged particle microscope with an adjustable image shell or field curvature, comprising the following: a multi-beam generator, which is configured to generate a first field of a multiplicity of charged first individual particle beams; a first particle optical unit with a first particle optical beam path, which is configured to image the generated first individual particle beams onto an object in the object plane such that the first individual particle beams impinge the object surface at incidence locations, which form a second field; a detection system with a multiplicity of detection regions that form a third field; a second particle optical unit with a second particle optical beam path, which is configured to image second individual particle beams, which emanate from the incidence locations in the second field, onto the third field of the detection regions of the detection system; a magnetic and/or electrostatic objective lens, through which both the first and the second individual particle beams pass; a beam switch, which is arranged in the first particle optical beam path between the multi-beam particle generator and the objective lens and which is arranged in the second particle optical beam path between the objective lens and the detection system; a sample stage for holding and/or positioning an object during the object inspection; and a controller; wherein the multi-beam charged particle microscope is adapted to operate at a plurality of working points, wherein operating the multi-beam charged particle microscope at the plurality of working points results in the first particle optical unit generating a respective plurality of spherically curved image fields in the object plane, which are to be pre-compensated by the multi-beam generator, wherein the multi-beam generator comprises
a filter plate comprising a plurality of filter apertures for generating the plurality of first individual particle beams, wherein the filter plate is connected during use to ground potential,
a stack of multi-aperture plates with at least a first multi-lens array for long range focal length variation, the first multi-lens array comprising
   a first multi-aperture plate comprising a plurality of first apertures, wherein the first multi-aperture plate is connected during use to ground potential,
   a second multi-aperture plate comprising a plurality of second apertures, wherein the second multi-aperture plate is connected during use to a first driving voltage, wherein the second plurality of apertures have diameters that vary according to a first function of the distance of the respective second aperture from the optical axis (A) of the multi-beam particle microscope, this first function being adapted to pre-compensate a spherically curved image shell in the object plane, and
   a third multi-aperture plate comprising a plurality of third apertures, wherein the third multi-aperture plate is connected during use to ground potential,
   wherein the centers of the pluralities of the first, the second and the third apertures are aligned with one another, and
a second multi-lens array for short range focal length variation,
wherein the second multi-lens array is aligned with the first multi-lens array, and wherein the second multi-lens array is configured to pre-compensate a residual image shell error in the object plane which is not pre-compensated by the first multi-lens array;
   wherein the controller is configured to provide a first driving voltage to the first multi-lens array based on the working point of the multi-beam particle microscope, and wherein the controller is configured to provide a second driving voltage to the second multi-lens array based on the working point of the multi-beam particle microscope.

It is to be noted that the potential to which first and third aperture plates are set can be any voltage, as only the potential difference to the particle source or electron source is of relevance. It is useful to set this potential to ground for practical reasons. In the remainder of this text, we denote with “ground potential” a reference potential for all other potentials mentioned.

The individual charged particle beams can be, e.g., electrons, positrons, muons or ions or other charged particles.

The apertures in the first and second multi-lens arrays are circular. Optionally, the apertures in the multi-lens arrays have a regular arrangement, for example a rectangular, square or hexagonal arrangement. Optionally, 3n(n−1)+1 apertures are provided in the case of a hexagonal arrangement, where n is any natural number.

The controller of the multi-beam charged particle microscope can comprise a plurality of control units. It is for example possible that each control unit of the multi-beam charged particle microscope controls one part or function of the multi-beam charged particle microscope. It is for example possible to provide a separate control unit for controlling the multi-beam generator.

According to the present disclosure, at least the second plurality of apertures of the first multi-lens array can have diameters that vary according to a first function of the distance of the respective second aperture from the optical axis of the multi-beam particle microscope. In other words, the aperture diameters can scale with r which is the distance to the optical axis Z. This does not, however, preclude that an offset is added to the distance r, thereby shifting the positions of the apertures within the second multi-aperture plate, even if this is not explicitly stated in the following text.

The plurality of first apertures of the first multi-aperture plate provided upstream of the second multi-aperture plate can have diameters that are constant, so can the third multi-aperture plate comprising the third plurality of third apertures. However, it is also possible that the plurality of first apertures and/or the plurality of third apertures have diameters that also vary according to the first function or according to another function.

The stack of multi-aperture plates can comprise at least the three plates of the first multi-lens array. Practically, it is possible that all of those multi-aperture plates are provided as separate plates. However, it is also possible to choose alternative design possibilities, for example providing different layers with apertures serving as the plates on a substrate.

Optionally, the filter plate is also provided as a separate plate. However, it is also possible to combine the filter plate with the first multi-aperture plate of the first multi-lens array.

The stack of multi-aperture plates can also comprise another multi-lens array for long range focal length variation. The entire stack can then for example comprise five multi-aperture plates forming two subsequent Einzel-lens arrays, each Einzel-lens array with apertures having diameters that vary according to the first function of the distance of the respective aperture from the optical axis. The third multi-aperture plate of the first Einzel-lens array can then also provide the first multi-aperture plate for the other Einzel-lens array. The provision of two Einzel-lens arrays in succession allows for reducing the voltage provided to the multi-aperture plates with the apertures of variable diameters. This can contributes to realizing an even bigger long range focal length variation.

In each case the stack of multi-aperture plates with at least the first multi-lens array can be configured for a long range focal length variation. Normally, this long range focal length variation provides most of the focal length variation to compensate for a field curvature in the object plane. In contrast thereto, the second multi-lens array for short range focal length variation can realize a comparatively shorter focal length variation. The second multi-lens array can pre-compensate the residual image shell error in the object plane. This residual image shell error is not pre-compensated by the first multi-lens array. In many cases, the residual image shell error is not only not pre-compensated by the first multi-lens array, but cannot be pre-compensated by the first multi-lens array in general. The pre-compensation of the residual image shell error can correct the shape of the image shell from a compressed or elongated image shell to a spherically curved image shell.

The first function applied for pre-compensating this spherically curved image shell in the object plane can in general be of any type. However, in practice, this first function normally comprises a quadratic dependency of the distance r to the optical axis Z of the multi-beam particle microscope. It then pre-compensates a parabolic image shell in the object plane or at least an image shell that is very similar to a spherical image shell. However, it is also possible that the first function as such already contains correction terms of higher order to generate a pre-compensated shape of the image shell that comes even closer to the ideal spherically curved image surface, at least for one working point.

According to an embodiment of the present disclosure, the diameter variation of the second apertures according to the first function in the second multi-aperture plate is optimum for pre-compensating during use a spherically curved image shell in the object plane at a pre-selected reference working point; wherein the controller is configured to provide a first driving voltage to the first multi-lens array at the reference working point which is not zero; and wherein the controller is configured to provide a second driving voltage to the second multi-lens array at the reference working point which is basically zero.

In other words, at the reference working point, it is possible to optimally pre-compensate the field curvature with only the first multi-lens array being active. The second multi-lens array is not for this correction at the reference working point. It is to be noted that the first driving voltage applied at the reference working point is not necessarily the maximum first driving voltage. Instead, it can be a small first driving voltage or a driving voltage of medium size when comparing the first driving voltages provided at the different working points.

According to an alternative embodiment, the first function in the second multi-aperture plate is designed such that the size of a residual image shell error that has to be corrected with the second multi-lens array does not exceed a predetermined limit. It is then possible that the first function cannot correct an image field curvature perfectly at a reference working point or at any other working point, but the entire adjustment for pre-compensating the field curvature can be carried out most conveniently because the residual image shell error can be well pre-compensated for all working points.

According to an embodiment, the controller of the multi-beam charged particle microscope is configured to provide a first driving voltage to the first multi-lens array at the second working point which is different from the first driving voltage provided at the reference working point and which is not zero; and wherein the controller is configured to provide a second driving voltage to the second multi-lens array at the second working point which is not zero.

Therefore, a change of the first driving voltage basically reflects the long range focal length variation that is involved due to the change of working point as such and the provision of the second driving voltage is basically responsible for the pre-compensation of the residual image shell error.

According to an embodiment the second multi-lens array comprises a fourth multi-aperture plate comprising a plurality of fourth apertures, wherein the fourth multi-aperture plate is connected during use to ground potential, a fifth multi-aperture plate comprising a plurality of fifth apertures, wherein the fifths multi-aperture plate is connected during use to a second driving voltage U2, wherein the plurality of fifth apertures have diameters that vary according to a second function of the distance r of the respective aperture from the optical axis Z of the multi-beam particle microscope, this second function being adapted to pre-compensate the residual image shell error in the object plane which is not pre-compensated by the first multi-lens array, and a sixth multi-aperture plate comprising a plurality of sixth apertures, wherein the sixth multi-aperture plate is connected during use to ground potential, wherein the centres of the pluralities of the fourth, the fifths and the sixths apertures are aligned with one another; and wherein the controller is configured to control the second driving voltage U2 provided to the fifth multi-aperture plate based on the working point of the multi-beam particle microscope.

According to this embodiment, the residual image shell error can basically be pre-compensated by another monolithic Einzel-lens array. The correction can be encoded in the diameter variation of the fifth apertures in the fifth multi-aperture plate. The second function can be a function of the distance r of the respective fifth apertures to the optical axis Z. This does not, however, preclude that an offset is added to the distance r, thereby shifting the positions of the apertures within the fifths multi-aperture plate, even if this is not explicitly stated in the following text.

It is also possible to combine the encoded residual error correction with an additional focal length variation as already encoded in the second multi-aperture plate of the first multi-lens array. This can contribute to a bigger entire range of focal length variation.

According to an embodiment, the first multi-lens array is provided in direct succession to the filter plate. In other words, the first multi-lens array is the first multi-lens array after the filter plate in the direction of the particle optical beam path through the multi-beam generator. The first multi-lens array can be directly followed by the second multi-lens array. However, it is also possible to flip the order of provision of the first multi-lens array and the second multi-lens array.

According to an embodiment, the third multi-aperture plate of the first multi-lens array and the fourth multi-aperture plate of the second multi-lens array are provided as the same multi-aperture plate. Alternatively, the first multi-aperture plate of the first multi-lens array and the sixth multi-aperture plate of the second multi-lens array are provided as the same multi-aperture plate. In both cases, overall, an alternating arrangement of multi-aperture plates connected to ground potential and multi-aperture plates connected to a driving voltage (and having variable apertures encoding correction) is provided. The last multi-aperture plate of the sequence is a multi-aperture plate connected to ground potential once again.

According to an embodiment, the first function f1(r) is a polynomial of degree n with n∈ [symbol] and n≥2. The polynomial can comprise a term of degree 2, only. However, the polynomial can also comprise terms of other degrees in addition. The first function can have the distance r to the optical axis as the only variable. However, the first function can depend on other variables as well, for example a cartesian coordinate like x or y, for example f1(r,x), f1(r,y) or f1(r,x,y).

According to an embodiment, the second function f2(r) is a polynomial of degree n with n∈ [symbol] and n≥4. Calculations of the inventors have shown that in many real multi-beam particle microscopes the residual error that has to be corrected is a polynomial of degree 4. In many cases, the second function is even and comprises for example only terms of degree 4 and 2. In other cases, the second function is a polynomial comprising only a term of degree 4, for example. The nature of the residual error that is corrected is determined in advance for the multi-beam particle microscope to be able to provide a specific higher order correction (third order correction in the exemplary described cases).

According to an embodiment, the second function f2 (r) is not the inverse function of the first function f1(r).

According to an embodiment of the disclosure, the second multi-lens array comprises a multi-aperture plate comprising a plurality of apertures with a plurality of individually addressable ring-electrodes being arranged around each aperture, wherein the controller is configured to provide an individual second driving voltage U2i to each of the ring-electrodes based on the working point of the multi-beam particle microscope.

According to this embodiment, the second multi-lens array can thus be realized by an active device. However, the issues arising in practice when using such active devices do not arise according to this specific embodiment. The active device is only applied for correcting the residual image shell error which does not involve the use of high voltages. Thus, there are no considerable insulation or short-circuiting issues.

According to an embodiment, for each of the second driving voltages U2i the following relation holds: 0V≤U2i≤20V, optionally 0V≤U2i≤10V. These driving voltages are about one order of magnitude lower than driving voltages used when applying the ring-shaped electrodes for long range focal length variations as attempted in certain known systems.

According to an embodiment, the following relation holds for the first driving voltage U1:

U1≤100V, optionally U1≤150V or U1≤200V or U1≤400V. The relations holds for each working point of the multi-beam particle microscope.

According to an embodiment, a ratio between a focal length variation Δz1 achieved with the first multi-lens array only and an overall achieved focal length variation Δz within the image field in the object plane is for all working points: Δz1/Δz≥0.80, optionally Δz1/Δz≥0.90, such as Δz1/Δz≥0.95.

The focal length variation is defined as the difference in focal length in the direction z for one image shell. The direction z is the propagation direction of the individual particle beams and is also parallel to the optical axis Z. The overall achieved focal length variation Δz can be the sum of the focal length variation Δz1 achieved with the first multi-lens array and the focal length variation Δz2 achieved with the second multi-lens array. However, other multi-lens arrays or other measures can further contribute to the overall achieved focal length variation Δz.

According to an embodiment, the multi-beam particle microscope is configured for pre-compensating a focal length variation Δz within the image field in the object plane for which the following relation holds: Δz≥1.0 m, optionally Δz≥3 μm, such as Δz≥12 μm. The overall focal length variation Δz that can be pre-compensated by the multi-beam generator of the present disclosure is therefore big and allows a correction of the field curvature of big image fields. An exemplary size of a big image field is 100 μm×100 μm, 200 μm×200 μm or 500 μm×500 μm or even bigger.

According to an embodiment of the disclosure, the multi-beam generator comprises at least one further multi-lens array contributing to a pre-compensation of the focal length variation within the image field in the object plane. This further multi-lens array can be a part of the stack of the multi-aperture plates and therefor basically contribute to the long range focal length variation. However, it can also be provided as further multi-lens array contributing to a pre-compensation of the residual image shell error. Optionally, a further multi-lens array can overall contribute to increasing the possible maximum focal length variation. Since a realization of a big focal length variation is really challenging, also small contributions to a possible focal length variation can be of high value in practise. Furthermore, one or more further multi-lens arrays can pre-compensate focal length variations within the image field of other kind than field curvature, for example a field inclination or tilt.

According to an embodiment of the disclosure, the multi-beam generator further comprises a first tilt compensation multi-lens array, comprising: a first multi-aperture plate comprising a plurality of first apertures, wherein the first multi-aperture plate is connected during use to ground potential, a second multi-aperture plate comprising a plurality of second apertures, wherein the second multi-aperture plate is connected during use to a first tilt driving voltage, wherein the diameters of the second apertures vary as a linear function f(x) of a position of the respective aperture in a direction x, the direction x being perpendicular to the optical axis Z, a third multi-aperture plate comprising a plurality of third apertures, wherein the third multi-aperture plate is connected during use to ground potential, wherein the centers of the pluralities of the first, the second and the third apertures are aligned with one another, and

wherein the controller is configured to provide the first tilt driving voltage to the first tilt compensation multi-lens array for example based on the working point of the multi-beam particle microscope.

The apertures in the first, second and third multi-aperture plate can be circular. The diameters of the apertures of the first multi-aperture plate and the third multi-aperture plate can be constant. However, they can alternatively vary in the same way as the second apertures in the second multi-aperture plate or in another way.

The first tilt compensation multi-lens array can be suited to compensate an image field inclination in the object plane. The reasons for an image field inclination or tilt can be numerous ones. The field inclination can occur due to aberrations or to an asymmetric beam splitter design, for example. Additionally or alternatively, it is also possible that an object in the object plane, for example a wafer surface, is not perfectly perpendicular to the optical axis Z of the multi-beam particle microscope.

According to an embodiment, the multi-beam generator further comprises a second tilt compensation multi-lens array, comprising: a fourth multi-aperture plate comprising a plurality of fourth apertures, wherein the fourth multi-aperture plate is connected during use to ground potential, a fifth multi-aperture plate comprising a plurality of fifth apertures, wherein the fifth multi-aperture plate is connected during use to a second tilt driving voltage, wherein the diameters of the fifth apertures vary as a basically linear function f(y) of a position of the respective aperture in a direction y, the direction y being perpendicular to the optical axis Z and linear independent from the direction x, and a sixth multi-aperture plate comprising a plurality of sixth apertures, wherein the sixth multi-aperture plate is connected during use to ground potential, wherein the centers of the pluralities of the fourth, the fifth and the sixth apertures are aligned with one another, and wherein the controller is configured to provide the second tilt driving voltage to the second tilt compensation multi-lens array for example based on the working point of the multi-beam particle microscope.

The second tilt compensation multi-lens array can therefore basically work in an analogous manner as already explained with respect to the first tilt compensation multi-lens array. Optionally, the directions x and y are perpendicular to one another.

Optionally, a third tilt compensation multi-lens array and/or a fourth tilt compensation multi-lens array are provided, allowing a tilt compensation in a direction −x as well as in a direction −y. A stack of four tilt compensation multi-lens arrays with compensation properties in direction x, −x, y and −y allows for compensation of a tilt in both directions along the x-axis and y-axis and therefore provides a possibility for correcting beam tilts in every desired direction.

Instead of providing four different tilt compensation multi-lens arrays, it is also possible to encode a bias tilt compensation in the first multi-lens array, for example. For example, according to an embodiment, the first function describing the diameter variation of the plurality of second apertures in the second multi-aperture plate of the first multi-lens array can be not only a function of the distance r from the optical axis Z, but also a linear function of a position of the respective apertures in a direction −x and/or in a direction −y, the directions −x, −y being perpendicular to the optical axis Z and being linear independent, optionally perpendicular, to each other, wherein the linear function of −x and/or −y is adapted to bias a field inclination in the object plane. The field inclination that can be biased can for example result from an asymmetric beam splitter design, but it can also have other reasons. In any case it is sufficient to provide only two further tilt compensation multi-lens arrays for an arbitrary tilt compensation, when a respectively large overall tilt is sufficiently biased.

According to an embodiment, the multi-beam generator further comprises a stigmation multi-aperture plate comprising a plurality of apertures with a plurality of individually addressable electrostatic multi-pole electrodes being arranged in the circumference of each aperture,

wherein the controller is configured to provide a set of driving voltages U4ij to each of the multi-pole electrodes, each set of driving voltages U4ij comprising an individual offset voltage U4ij_{offset} common to all electrodes of a respective multi-pole electrode based on the working point of the multi-beam particle microscope.

The multi-pole electrodes can for example be 8-pole electrodes or 12-pole electrodes or the like. When the segmented electrodes arranged in the circumference of a specific aperture are provided with the same potential, the effect of the multi-pole electrode is basically the same as the effect of a ring-electrode which allows an adaptation of a focal length variation when the ring-electrode is part of an Einzel-lens system. By individually adjusting an offset voltage U4ij_{offset} the overall range for a focal length variation and thus the possibilities for a pre-compensation of the field curvature (or an image field inclination as well) can be improved.

In general, an order of different correctors within the multi-beam generator, for example an order of the multi-lens arrays, the tilt-compensation multi-lens arrays and the stigmation multi-aperture plate within the multi-beam generator, can be freely chosen. However, it can be advantageous to provide the stigmation multi-aperture plate as the first corrector in the sequence of correctors, because this position might have advantages from an alignment/adjustment perspective.

According to an embodiment of the disclosure, the multi-beam generator comprises in this order:
a terminating multi-aperture plate with a plurality of terminating apertures, wherein a diameter of the terminating apertures varies as a function of the distance of the respective aperture from the optical axis, and wherein the terminating multi-aperture plate is connected during use to ground potential,
an electrode aperture plate with a single opening through which all first individual particle beams pass, wherein the electrode aperture plate is connected during use to an extraction voltage,
wherein the centers of the terminating multi-aperture plate and the electrode aperture plate are aligned with one another;
wherein the controller is configured to provide the extraction voltage to the electrode aperture plate based on the working point of the multi-beam particle microscope, thereby varying an extraction field and thus an immersion lens effect contributing to the focal length variation.

The terminating multi-aperture plate is the last multi-aperture plate in the multi-beam generator when described in the direction of the particle optical beam path. This terminating multi-aperture plate can for example be the last multi-aperture plate of the second multi-lens array for short range focal length variation, however, it can also be another multi-aperture plate of another multi-lens array or it can even be provided separately.

The effect described above can be further enhanced when a shape of the terminating multi-aperture plate additionally varies as a function of the distance r from the optical axis Z. It has turned out that this additional variation is extremely efficient and sensitive to a focal length variation.

Varying the shape of the terminating multi-aperture plate can for example be achieved by a thickness variation of the terminating multi-aperture plate. According to an embodiment, an upper surface of the terminating multi-aperture plate is plane and a bottom surface of the terminating multi-aperture plate is shaped convex with respect to the direction of the particle optical beam path or, alternatively, the bottom surface of the terminating multi-aperture plate is shaped concave with respect to the direction of the particle optical beam path. The specific shape of the bottom surface of the terminating multi-aperture plate additionally varies a distance between the electrode aperture plate on the one hand and the respective terminating apertures of the terminating multi-aperture plate on the other hand. This contributes to a further variation of the extraction field which contributes to a focal length variation.

Further investigations of the inventors have shown that a focal length variation can be further increased by optimizing plate dimensions, for example plate dimensions of the first multi-lens array which is applied for the long range focal length variation. The biggest field curvature correction potential can be realized for the shortest electrode length of the second multi-aperture plate, the smallest gaps between the first and second multi-aperture plate as well as between the second and third multi-aperture plate of the first micro-lens array and by using counter-electrodes of the Einzel-lens systems with smallest thickness. In more detail, the following geometric conditions can be used:

According to an embodiment, the following relation holds for a thickness L2 of the second multi-aperture plate of the first multi-lens array: L2≤50 μm, optionally L2≤30 μm.

According to an embodiment, the following relation holds for a thickness L1 of the first multi-aperture plate of the first multi-lens array: L1≥80 μm, optionally L1≥100 μm, and/or

the following relation holds for a thickness L3 of the third multi-aperture plate of the first multi-lens array: L3≥80 μm, optionally L3≥100 m.

According to an embodiment, the following relation holds for a gap G1 between the first multi-aperture plate and the second multi-aperture plate of the first multi-lens array: G1≤10 μm, optionally G1≤5 μm; and/or the following relation holds for a gap G2 between the second multi-aperture plate and the third multi-aperture plate of the first multi-lens array: G2≤10 μm, optionally G2≤5 μm.

In general, the above findings concerning the dimensions of the Einzel-lens array can be transferred to other multi-lens arrays as well.

According to an embodiment, the multi-beam generator further comprises a mechanism for generating a voltage gradient on the second multi-aperture plate of the first multi-lens array, and the controller is configured to provide gradient driving voltages to the second multi-aperture plate in order to pre-compensate a field inclination in the object plane. Since the focal length variation depends on the applied voltage, the provision of a voltage gradient can further contribute to a focal length variation. The provision of a voltage gradient provides another possibility for adapting a linear variation of the focal length.

According to an embodiment, the second multi-aperture plate comprises on its surface a high-resistance coating which is contacted on opposing sides of the second multi-aperture plate to generate an adjustable voltage gradient. There can be, for example, two opposing contacts, for example elongated contacts, but there can also be more pairs of opposing contacts. Additionally or alternatively, another pair of opposing contacts can be provided in such an arrangement that an additional gradient can be provided into a further direction, optionally in an orthogonal direction to the gradient direction generated by the first pair of opposing contacts.

According to an of the disclosure, the multi-beam particle microscope further comprises a mechanism for in situ plasma cleaning of monolithic multi-aperture plates; and/or the multi-beam particle microscope comprises a mechanism for providing a small partial pressure of hydrogen gas during use of the multi-beam particle microscope for cleaning purposes. The hydrogen can be provided continuously during operation of the multi-beam particle microscope or it can provided in a pulsed manner or intermittently between different recordings or imaging of different frames or in general in a pause of an imaging process. Additionally or alternatively, a mechanism for continuously heating the monolithic multi-aperture plates can be provided. The heating contributes to cleaning the monolithic multi-aperture plates. Cleaning can be suited if only passive correction devices such as the monolithic multi-aperture plates are applied. Furthermore, the cleaning can be relevant because impurities or debris at the apertures with precisely varying diameters can deteriorate the high precision correction that is used for pre-compensating a field curvature or image field tilt.

The embodiments of the first aspect of the disclosure can be combined fully or in part with one another, as long as no technical contradictions occur.

According to a second aspect of the disclosure, the disclosure is directed to a multi-beam generator for a charged-particle multi-beam system, comprising the following:
a filter plate comprising a plurality of filter apertures for generating a plurality of first individual particle beams, wherein the filter plate is connected during use to ground potential,
a stack of multi-aperture plates with at least a first multi-lens array for long range focal length variation, the first multi-lens array comprising
   a first multi-aperture plate comprising a plurality of first apertures, wherein the first multi-aperture plate is connected during use to ground potential,
   a second multi-aperture plate comprising a plurality of second apertures, wherein the second multi-aperture plate is connected during use to a first driving voltage, wherein the second plurality of apertures have diameters that vary according to a first function of the distance of the respective second aperture from the optical axis (A) of the multi-beam system, this first function being adapted to pre-compensate a spherically curved image field in an object plane of the multi-beam system, and
      a third multi-aperture plate comprising a plurality of third apertures, wherein the third multi-aperture plate is connected during use to ground potential,
      wherein the centers of the pluralities of the first, the second and the third apertures are aligned with one another, and
   a second multi-lens array for short range focal length variation,
      wherein the second multi-lens array is aligned with the first multi-lens array, and
      wherein the second multi-lens array is configured to pre-compensate a residual image field error in the object plane which is not pre-compensated by the first multi-lens array, and
a control unit,
wherein the control unit is configured to provide a first driving voltage to the first multi-lens array based on a working point of the multi-beam system, and
wherein the control unit is configured to provide a second driving voltage to the second multi-lens array based on the working point of the multi-beam system.

The multi-beam generator can be provided with some or all the features as already described with respect to the first aspect of the disclosure directed to a multi-beam charged-particle microscope comprising the multi-beam generator. Of course, the multi-beam generator can also be applied in other charged-particle multi-beam systems. Explicit reference is once again made to the first aspect of the disclosure.

### BRIEF DESCRIPTION OF THE DRAWINGS

In the accompanying figures:

FIG. 1: shows a schematic representation of a multi-beam particle microscope (MSEM);

FIG. 2: shows an example of a multi-beam generator;

FIGS. 3a, b: schematically illustrate an effect of a field curvature and an image field inclination on the resolution of a multi-beam particle system;

FIGS. 4a,b: schematically illustrate an effect of a pre-compensation of an image curvature and an image field inclination on the resolution of a multi-beam particle system;

FIGS. 5a, b: schematically illustrate an aspect of the field curvature correction according to the present disclosure;

FIG. 6: schematically illustrates a multi-beam generator according to the disclosure;

FIGS. 7a, b: show exemplarily a top view of a multi-aperture plate with varying aperture diameters;

FIGS. 8a, b: is a graphic representation of residual image shell errors;

FIG. 9: schematically depicts multi-aperture plates with varying aperture diameters;

FIGS. 10a, b: schematically depict multi-aperture plates of tilt compensation multi-lens arrays;

FIGS. 11a, b: schematically depict another multi-aperture plate of the multi-beam generator;

FIG. 12: schematically depicts a multi-beam generator according to the present disclosure;

FIG. 13: schematically depicts a terminating multi-aperture plate with varying shape;

FIG. 14: schematically depicts a terminating multi-aperture plate with varying shape;

FIG. 15: schematically depicts a multi-beam generator according to the present disclosure;

FIG. 16: schematically depicts a multi-beam generator according to the present disclosure;

FIG. 17: schematically depicts a multi-beam generator according to the present disclosure; and

FIG. 18: schematically illustrates dimensions of a multi-lens array.

### DETAILED DESCRIPTION

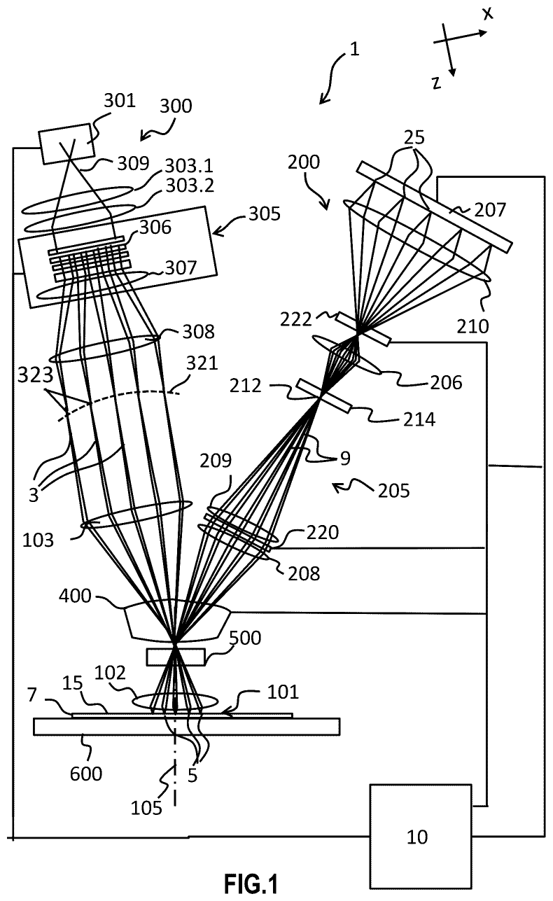

FIG. 1 schematically shows a multi-beam particle microscope 1. The multi-beam particle microscope 1 comprises a beam generating apparatus 300 with a particle source 301, for example an electron source. A diverging particle beam 309 is collimated by a sequence of condenser lenses 303.1 and 303.2 and impinges on a multi-aperture arrangement 305. The multi-aperture arrangement 305 comprises a plurality of multi-aperture plates 306 and a field lens 307. A plurality of individual particle beams 3, for example individual electron beams 3, are generated by the multi-aperture arrangement 305. Centre points of apertures of the multi-aperture plate arrangement 305 are arranged in a field which is imaged onto another field formed by beam spots 5 in the object plane 101. The distance between centres of apertures of a multi aperture plate 306 may be, for example, 5 μm, 100 μm, and 200 μm. The diameters D of the apertures are smaller than the distance between the centres of the apertures, examples of the diameters are 0.2 times, 0.4 times and 0.8 times the distances between the centres of the apertures.

The multi-aperture arrangement 305 and the field lens system 308 are configured to produce a plurality of focal points 323 of the first individual particle beams 3 in a raster arrangement in a plane 321. The plane 321 need not be a flat plane, but may be a spherically curved surface to pre-compensate an image field curvature of the subsequent particle optical system. Alternatively, the beam foci 323 can be virtual. A diameter of the beam foci 323 can be for example, 10 nm, 100 nm and 1 μm.

The multi-beam particle microscope 1 further comprises a system of electromagnetic lenses 103 and an objective lens 102 that image the beam foci 323 from the intermediate image plane 321 into the object plane 101 in a reduced size. The first individual particle beams 3 pass a beam splitter 400 and a collective beam deflection system 500, which is used to deflect the plurality of first individual particle beams 3 in operation and scan the image field. The first individual particle beams 3 impinging into the object plane 101 form, for example, a substantially regular field or array, wherein distances between adjacent locations of incidence or beam spots 5 may be, for example, 1 μm, 10 μm or 40 μm. The field formed by the locations of incidence or beam spots 5 may have, for example, a rectangular or a hexagonal symmetry. A diameter of the beam spots 5 shaped in the object plane 101 can be small. Exemplary values of the diameter are 1 nm, 5 nm, 10 nm, 100 nm and 200 nm. The focusing of the individual particle beams 3 for shaping the beam spots 5 is carried out by the objective lens system 102.

The object to be inspected may be of any type, for example a semiconductor wafer or a biological sample, and it may comprise an arrangement of miniaturized elements or the like. The surface 15 of the object 7 is arranged in the object plane 101 of the objective lens 102. The objective lens 102 may comprise one or more electron optical lenses. For example, it may be a magnetic objective lens and/or an electrostatic objective lens.

The primary particles 3 impinging the object 7 generate interaction products, e.g. secondary electrons, back-scattered electrons or primary particles that have experienced a reversal of movement for other reasons, which emanate from the surface of the object 7 or object plane 101. The interaction products emanating from the surface 15 of the object 7 are shaped by the objective lens 102 to form secondary particle beams 9 or second individual particle beams 9. Thereby, the secondary particle beams 9 pass through the beam splitter 400 arranged after the objective lens 102 and are guided along a particle optical beam path to a projection system 200. The projection system 200 comprises an imaging system 205 with a plurality of projection lenses or projection lens systems 208, 209, 210, a contrast aperture 214, and a multi-particle detector 207. Locations of incidence 25 of the secondary individual particle beams 9 on detection areas of the multi-beam particle detector 207 are in a third field with a regular spacing between the locations of incidence. Exemplary values are 10 μm, 100 μm and 200 μm.

The multi-beam particle microscope 1 further comprises a computer system or control unit 10, which in turn may be of single-part or multi-part design, and which is designed both to control the individual particle-optical components of the multi-beam particle microscope 1 and to evaluate and analyze the signals obtained with the multi-detector 207 or the detection unit 207.

Further information on such multi-beam particle beam systems or multi-beam particle microscopes and components used therein, such as particle sources, multi-aperture plates and lenses, can be obtained from the international patent applications WO 2005/024881 A2, WO 2007/028595 A2, WO 2007/028596 A1, WO 2011/124352 A1 and WO 2007/060017 A2 and the German patent applications DE 10 2013 016 113 A1 and DE 10 2013 014 976 A1, the disclosure of which in the full scope thereof is incorporated by reference in the present application.

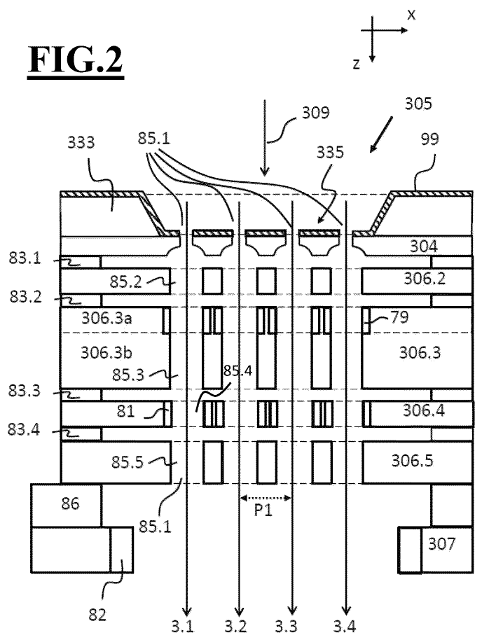

FIG. 2 shows an example of a multi-beam generator 305. According FIG. 2, the multi-beam generator 305 comprises in z-direction of the propagating electrons a sequence of five multi-aperture 5 plates 304 and 306.2 to 306.5, and a global lens 307. Each multi aperture plate 304 and 306.2 to 306.5 comprise a plurality of apertures 85.1 to 85.5, spaced at the same lateral distance P1 in each plate and each plate aligned such that a plurality of primary charged particle beamlets 3 is generated and shaped. The plurality of multi-aperture plates 304 and 306.2 to 306.5 and global lens electrode 307 are spaced by spacers 83.1 to 83.4 and spacer 86. The multi-beam generating unit 305 is illustrated in cross section (x,z) with only four apertures 85.1 to 85.5 in each multi-aperture plate shown, with the inner membrane zone 335 and the support zone 333. Parts of a collimated incident electron beam 309 pass the apertures 85.1, thereby forming the plurality of individual charged particle beams 3. The filter plate 304 has a metal layer 99 on the beam entrance side for stopping and absorbing the impinging electron beam 309 in the circumference of the plurality of apertures 85.1. The bulk material of the filter plate 304 is made of a conductive material, for example of doped silicon, and is connected to ground level. The second multi aperture plate 306.2 is a ground electrode plate. The second multi aperture or ground electrode plate 306.2 is made of conductive material, for example doped silicon, and is connected to ground level (0V). The third multi-aperture plate 306.3 is a two-layer lens-let plate with a first layer 306.3a comprising a plurality of ring electrodes 79 for the plurality of apertures, each configured to individually change a focus position of a corresponding primary charged particle beamlets, for example the charge particle beamlets 3.1 to 3.4. The second layer 306.3b, downstream of the first layer 306.3a, is isolated from the first layer and made of conductive material such as doped silicon. The second layer 306.3b is connected to ground level (0V). The ground electrode plate 306.2, the first layer 306.3a and the second layer 306.3b form during use a plurality of individually adjustable Einzel lenses for the plurality of primary charged particle beamlets 3. The multi-beam generating unit 305 further comprises a fourth multi-aperture or multi-stigmator plate 306.4. The multi-stigmator-plate comprises a plurality of four or more electrodes 81, for example eight electrodes for each of the plurality of apertures 85.4 (not labelled in FIG. 2). During use, different voltages in the range between −20V to +20V can be provided to each of the electrodes, and thereby each beamlet 3.1 to 3.4 can be influenced individually. For example, with an antisymmetric voltage difference, each beamlet 3.1 to 3.4 can be deflected in each direction by up to few μm to pre-compensate a distortion aberration of the illumination unit 100. For example, an astigmatism of each beamlet 3.1 to 3.4 can be compensated. With an offset voltage, each multi-pole element can additionally perform as an Einzel lens. Each multi-pole element can form an offset of a round lens field together with the second layer 306.3b and the hybrid lens plate 306.5, which are both connected to ground level (0V or a suitable reference potential). Thereby, a focusing range DF is additionally increased. The fifth multi-aperture plate or hybrid lens plate 306.5 is fabricated from doped silicon and forms a further electrode connected to ground level. In the example of FIG. 2, the first condenser lens 307 is connected to the multi-beam generator 305. The global lens 307 comprises a ring electrode 82, to which a high voltage of 3 kV to 20 kV can be applied, for example 12 kV to 17 kV. The lens 307 forms on the one hand a global electrostatic lens field for a global focusing action on the plurality of primary charged particle beamlets 3, including beamlets 3.1-3.4. The electrostatic lens fields penetrate the apertures of the hybrid lens plate 306.5, for example into each of the apertures 85.5, and an additional electrostatic lens field with focusing power is generated in each aperture of the hybrid lens plate 306.5. The electrostatic lens fields of hybrid lens plate 306.5 can however not be individually adjusted, and do not allow a compensation of a variable image plane tilt or a variable amount of field curvature. With the optional further field lens 308, each of the plurality of primary charged particle beamlets 3 including the beamlets 3.1 to 3.4 is focused during use into the curved and tilted intermediate image plane 321 to form focus stigmatically corrected spots.

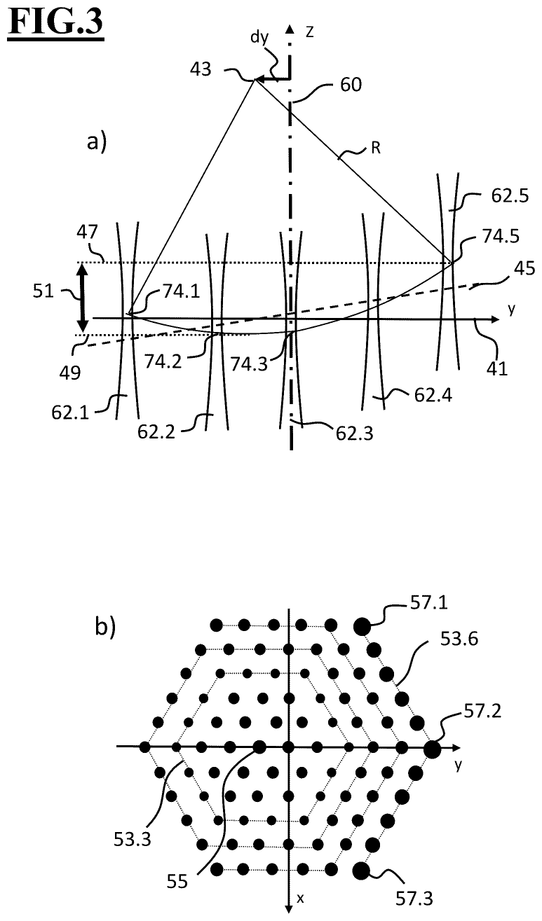

FIGS. 3a, b schematically illustrate the effect of a field curvature and an image field inclination on the resolution of a multi-beam particle system. FIGS. 3a, b illustrates geometric characteristics at the focal plane in a sectional view. Exemplarily illustrated are five beam cones 62.1 to 62.5 of individual primary beams 3 in the vicinity of a focal plane. Each beam cone 62.1 to 62.5 has a beam waist with a minimal spot extent 74.1 to 74.5. The beam waists 74.1 to 74.5 are positioned on a curved surface which is spherical and has a radius R, or can be approximated by a sphere with radius R. Furthermore, the center 43 of the spherical image field is not positioned on the optical axis Z, the image curvature is thus not symmetric to both sides of the optical axis Z. This is due to the present field inclination or image plane tilt indicated by line 45 in FIG. 3a.

As a consequence of the image field curvature and the image plane tilt there is no sharp focal plane, but an interval 51 between a lower focal plane 47 and an upper focal plane 49. Additionally, FIG. 3a shows a y-Axis through the position of the axial primary beam which is indicated with reference sign 41 inside the figure.

FIG. 3b shows a cut through FIG. 3a along the y-axis, so that the x,y-plane corresponds to the paper plane in FIG. 3b. Depicted is the resolution when imaging an object situated within the x,y-plane. The resolution is best for the minimum beam waists 74.1 to 74.5; however, only part of the beam waists 74.1 to 74.5 are arranged exactly within the object plane or x,y-plane. The spot sizes shown in FIG. 3b correspond to the beam cone diameters in the x,y-plane or object plane 101. FIG. 3b shows a variation of the resolution which has a rather concentric structure with respect to a spot 55 which is, however, not the beam waist of the central beam cone 62.3, but a neighbored beam cone 62.2. The dots 53.6 indicate approximately concentric rings or hexagons with focal points having a similar resolution. On the right-hand side and indicated by reference signs 57.1, 57.2 and 57.3, beam cone diameters that are too large to meet a resolution criterion for the multi-beam charged particle microscope or any other multi-beam system are depicted. Thus, appropriate correction of the image field in the object plane 101 is used. It is desirable to pre-compensate the field curvature as well as a field inclination in order to achieve a uniform resolution of the plurality of individual particle beams 3.

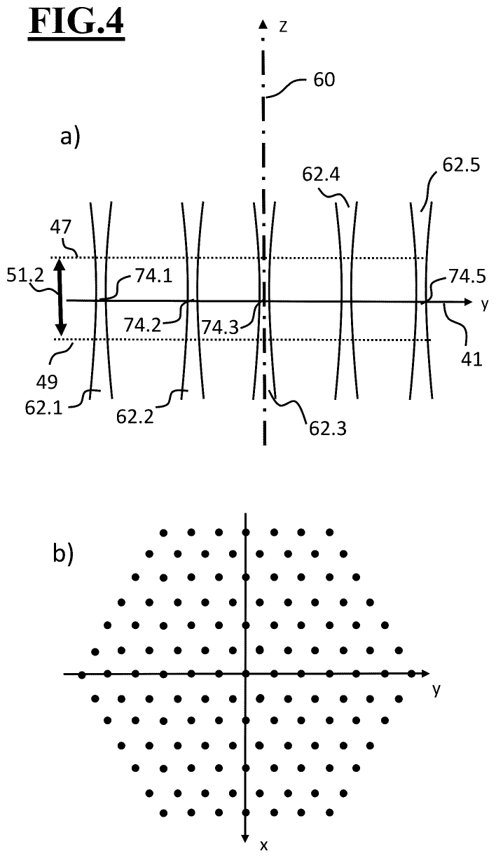

FIGS. 4a, b schematically illustrate the effect of a successful pre-compensation of an image curvature and an image field inclination on the resolution of a multi-beam particle system. Contrary to the situation as depicted in FIG. 3a, in FIG. 4a all beam waists 74.1 to 74.5 are positioned exactly on the y-axis. There is no image field curvature and no field inclination.

Consequently, as depicted in FIG. 4b, the resolution within the object plane or the x,y-plane is highly uniform: the spot size corresponding to the size of the beam cone in the object plane 101 is small for each of the first individual particle beams 3.

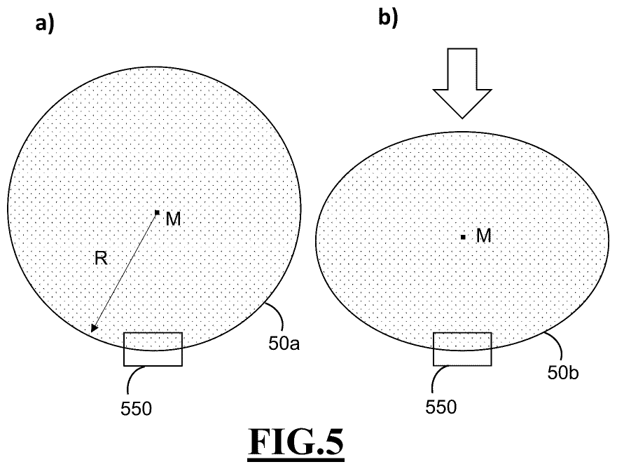

FIGS. 5a, b schematically illustrate an aspect of the field curvature correction according to the present disclosure. FIG. 5a schematically depicts an image shell 50a which is spherical and has a radius R around a center M. The spherical image shell 50a corresponds to a field curvature at a first working point. A change of working point, such as a change of the beam pitch, the magnification, the landing energy, the working distance and so on, leads to changes of the refractive power of the particle optical lenses of the multi-beam charged particle microscope or system. Changes of the refractive power result in the generation of different field curvatures in the object plane. Thereby, another sphere with another radius R′ would be generated. Therefore, adapting a field curvature pre-compensation to a change of working point involves finding a suitable transformation in the pre-compensator or multi-beam generator used.

However, when applying the passive concepts using Einzel-lens systems with varying aperture diameters have a deficiency here: if the image curvature is tuned by varying the driving voltage applied to the middle electrode of the micro-Einzel lens array, the difference in the focal length variation is linear for all individual particle beams. On the other hand, there is mathematically no linear scaling when trying to scale a first sphere with a first radius (corresponding to a first image field curvature) into a second sphere with a second radius (corresponding to a second image field curvature). Thus, as solely linear scaling by simply tuning the applied voltage can lead to an imperfect field curvature correction. In other words, any linear scaling of a spherical field curvature using the passive devices does not result in a bigger or smaller sphere, but in a “compressed” or “elongated” “sphere” which is strictly speaking no sphere anymore. This is exactly what is indicated in FIG. 5b: on the right-hand side there is shown a “compressed sphere” 50b which is an ellipsoid.

FIGS. 5a, b depict for ease of illustration the entire image shells 50a and 50b. However, in practice, only part of the sphere 50a or the ellipsoid 50b is of importance and corresponds to the actual image field. This region is schematically indicated by a box 550 in both sides of FIGS. 5a, b. The mistake that is made by approximating the ellipsoid 50b as a sphere as small, but it makes a difference when applying large image field sizes working with a high number of individual particle beams, for example when carrying out imaging processes using a high resolution.

Therefore, the disclosure takes the new approach to carry out a two-step correction of the field curvature: according a first step, a long range focal length variation is carried out using a micro-Einzel lens array with a plurality of apertures with variable diameters at a selected working point. Second, the specific error made in the long range focal length variation at the selected working point is specifically corrected by a subsequent short range focal length variation. This error correction can either be encoded in a second micro-Einzel lens array with a plurality of apertures with an error specific variation of the aperture diameters or by an active correction device using for example individually adjustable ring-electrodes. Coming back to the illustrative FIGS. 5a, b, the long range focal length variation ignores the mistake that is made when changing the working point and treats the ellipsoid 50b as if it was a sphere 50a. However, the short range focal length variation then corrects exactly the mistake.

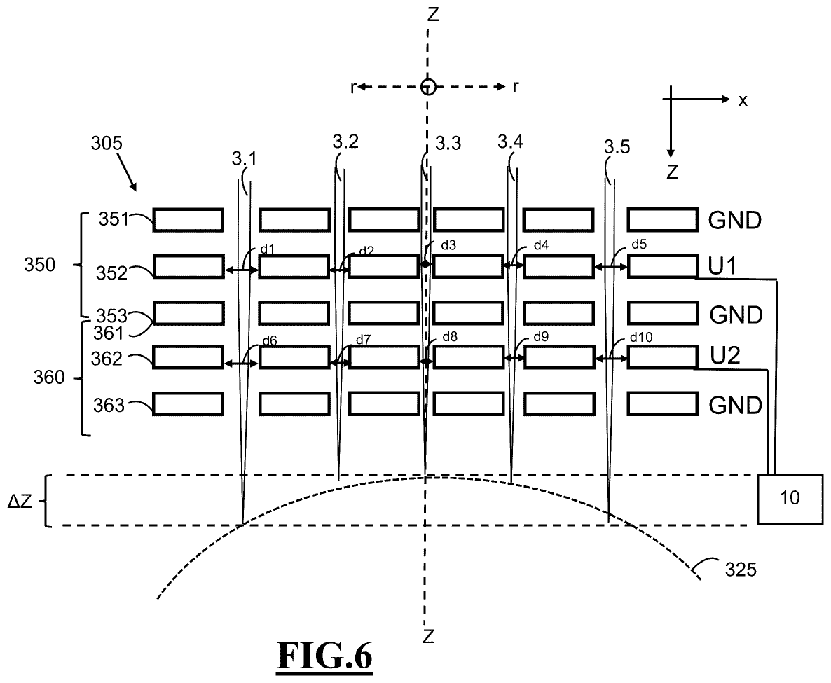

FIG. 6 schematically illustrates a multi-beam generator 305 according to the present disclosure. The multi-beam particle generator 305 comprises a first multi-lens array 350 and a second multi-lens array 360 in the embodiment shown. Furthermore, the multi-beam generator 305 can additionally comprise other components not depicted in FIG. 6, for example a filter plate comprising a plurality of filter apertures for generating the plurality of first individual particle beams.

The first multi-lens array 350 is provided for long range focal length variation and comprises a first multi-aperture plate 351 comprising a plurality of first apertures, wherein the first multi-aperture plate 351 is connected during use to ground potential. It further comprises a second multi-aperture plate 352 comprising a plurality of second apertures, wherein the second multi-aperture plate 352 is connected during use to a first driving voltage U1. The second plurality of apertures have diameters d1, d2, d3, d4 and d5 which vary according to a first function f1 of the distance r of the respective second aperture from the optical axis Z of the multi-beam particle microscope. In the example shown, an individual first particle beam 3.3 is provided on the optical axis Z. On the optical axis Z, the diameter d3 of the second multi-aperture plate 352 is minimum. The diameters d2 and d4 of the two neighboring apertures in the second multi-aperture plate 352 are bigger and the diameters d1=d4 through which the particle beams 3.1 and 3.5 pass, respectively have the largest diameter. The first function f1 describing the diameter of the apertures of the second multi-aperture plate 352 is adapted to pre-compensate a spherically curved image shell in the object plane. Focus points of the first individual particle beams 3.1 to 3.5 are formed in an intermediate image plane 321 having a spherically curved surface, accordingly. The focal length variation Δz is defined as the variation of the focal length in z-direction. The pre-compensation achieved with the first multi-lens array 350 can be optimum for a first image shell. The diameters d1 to d5 can be selected appropriately. For example, the first function f1(r) can be a polynomial of degree 2 and more generally a polynomial of degree n with n∈N and n≥2.

The second multi-lens array 360 is provided for short range focal length variation. In the example shown, the second multi-lens array 360 comprises a fourth multi-aperture plate 361 comprising a plurality of fourth apertures, wherein the fourth multi-aperture plate 361 is connected during use to ground potential. A fifth multi-aperture plate 362 is provided comprising a plurality of fifth apertures with diameters d6 to d10. This fifth multi-aperture plate 362 is connected during use to a second driving voltage U2. The plurality of fifth apertures have diameters d6 to d10 that vary according to a second function f2 of the distance r of the respective aperture from the optical axis Z of the multi-beam particle microscope 1, this second function being adapted to pre-compensate the residual image shell error in the object plane 101 which is not pre-compensated by the first multi-lens array 350. Furthermore, a sixth multi-aperture plate 363 comprising a plurality of six apertures is provided, wherein the sixth multi-aperture plate 363 is connected during use to ground potential. The centers of all apertures of all multi-aperture plates 351, 352, 353, 361, 362, 363 are aligned with one another and the apertures are circular in each case. The controller 10 or a separate control unit of the controller 10 is configured to control the second driving voltage U2 provided to the fifth multi-aperture plate 362 based on the working point of the multi-beam particle microscope 1.

The diameters d6 to d10 are normally not identical to the diameters d1 to d5. Instead, diameters d6 to d10 encode the second function f2(r). According to an embodiment, the function f2(r) is a polynomial of degree n with n∈N and n≥4. Therefore, the second function encodes an error correction for the image shell of third order or higher. Normally, the second function f2(r) is also not the inverse function of the first function f1(r).

The diameters of the holes in the plates 351, 353, 361, or 363 need not be the same as those of the corresponding holes in plates 352 or 362. They might be scaled from these diameters, or even the same within each plate.

Instead of providing the second multi-lens array 306 as micro-Einzel lens array with apertures of varying diameter, a plurality of individually addressable ring-electrodes being arranged around each aperture can be used. The controller 10 or a respective controller unit can then provide individual second driving voltages U2i to each of the ring-electrodes on the working point of the multi-beam particle microscope.

A voltage U1 or U2 that can be applied to the monolithic multi-aperture plates 352 or 362 can be comparatively high, for example U1≤100 V, optionally U1≤150 V or U1≤200 V or U1≤400 V. U2 can be of the same order of magnitude, but is normally lower since U2 is normally applied for short focal length variations, only. However, technically, U2 can be as high as U1.

In contrast thereto, a voltage provided as the second driving voltage U2i to an individually addressable ring electrode can be much more limited in order to avoid insulation or short-circuiting issues. According to an embodiment, the following relation holds for the second driving voltages U2i: 0 V U2i≤20 V, optionally 0 V≤U2i≤10 V.

A ratio between a focal length variation Δz1 achieved with a first multi-lens array 350 only and an overall achieved focal length variation Δz within the image field in the object plane 101 holds for all working points: Δz1: Δz≥0.90, optionally Δz1: Δz≥0.95. It is noted that the above ratio is identical when determined with respect to the intermediate image plane 321 or when determined with respect to the object plane 101. In practice, a total focal length variation Δz can be Δz≥3 μm, optionally even more, for example Δz≥12 μm.

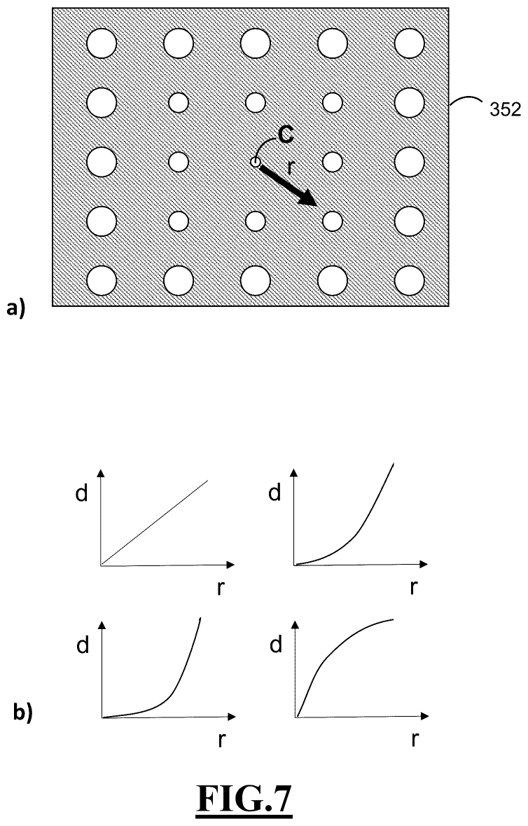

FIG. 7a shows exemplarily a top view of a multi-aperture plate with varying aperture diameters. As an example, a possible realisation of the second multi-aperture plate 352 of the first multi-lens array 350 for long range focal length variation is depicted. The second multi-aperture plate 352 is connected during use to a first driving voltage U1. The diameters of the apertures in the second multi-aperture plate 352 show a radial dependency. In other words, the diameters of the apertures vary as a first function of the distance r of the respective second aperture from the optical axis Z which runs through the centre C into the paper plane in the example shown. The diameter of the aperture provided at the centre C is the aperture with the minimum diameter. The overall arrangement is therefore centred.

FIG. 7b depicts exemplarily first functions f1 for varying the diameters of the apertures: in general, different functions and dependencies of r can be chosen for the diameters of the apertures d. The diameters of the apertures can vary for example linear, quadratic, cubic, hyperbolic and so on. In general it is also possible to use different sets of multi-aperture plates 352i with different dependencies of r and by this measure to approximate a required field curvature correction by varying the voltages Ui of the plates accordingly. A whole Taylor series of plates could be applied. However, according to the disclosure, it has turned out that the provision of such a big set is not necessary, but that in general already two micro-Einzel-lens arrays 350, 360 are sufficient: the first micro-Einzel-lens array 350 is used for the long range focal length variation and the second multi-lens array 360 is used for the short range focal length variation. Therefore, in practise, the second multi-aperture plate 352 of the first multi-lens array 350 normally comprises a quadratic dependency of r for the diameter variation.

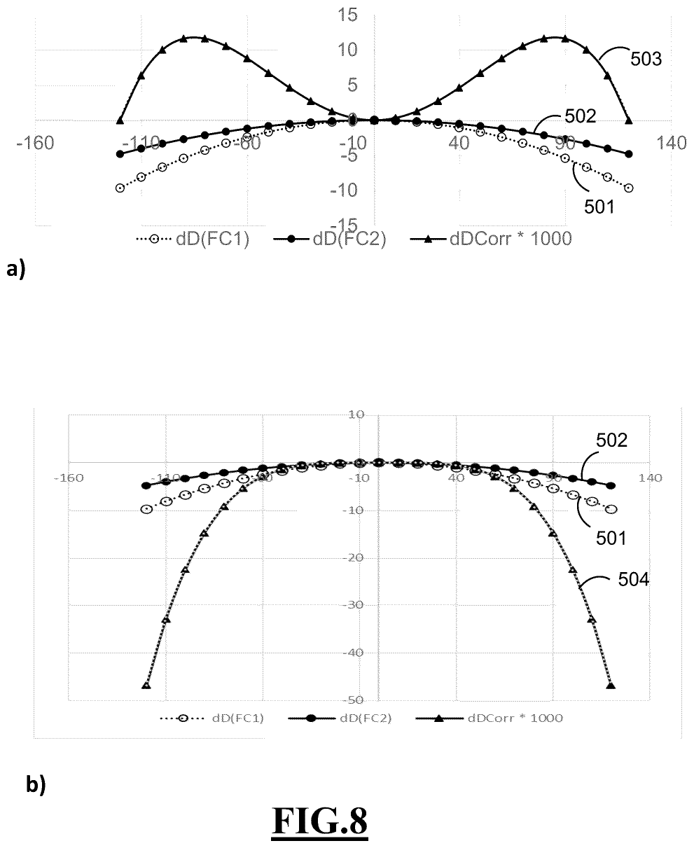

FIGS. 8a, b are graphic representations of residual image shell errors that can be corrected according to the present disclosure with the second multi-lens array 360 for short range focal length variation. In more detail, FIG. 8a depicts a first image shell 501 corresponding to a first working point. The image shell 501 is spherical and has a first radius corresponding to a first field curvature FC1. Furthermore, a second image shell 502 is depicted which is also spherical and has a second radius corresponding to a second field curvature FC2. The image shells 501 and 502 are ideal and shall be pre-compensated by using the multi-beam generator 305 according to the disclosure. Basically, for changing the first image shell 501 to the second image shell 502, the first multi-lens array 350 for long range focal length variation is applied. More concretely, the first driving voltage U1 is applied to the second multi-aperture plate 352 comprising the plurality of second apertures with a varying diameter of the apertures, for example a quadratic variation. However, a linear scaling of the first driving voltage U1 cannot exactly transform the first image shell 501 into the second image shell 502, since all focal lengths are changed in a linear way in z-direction. In other words, there does not exist any linear scaling in z-direction that could transform the first image shell 501 into the second image shell 502. The residual image shell error that is made by the linear scaling of the voltage is depicted as graph 503 in FIG. 8a. It is noted that the depicted residual image shell error is enhanced by a factor 1000. The mathematical nature of this residual image shell error is a polynomial of degree 4 comprising terms of degrees 4 as well as well terms of degree 2. This characteristic is found for all possible changes of working points in this specifically simulated multi-beam particle microscope. Therefore, it is possible to encode the residual image shell error correction as a polynomial according to graph 503 in a multi-aperture plate 362 with apertures of varying diameters. In other words, the graph 503 corresponds to the second function f2 (r) correcting the residual image shell error.

FIG. 8b shows a second example for a transformation from a first image shell 501 to a second image shell 502. Here, a slightly different design of the multi-beam generator was used as a basis for the simulation. Once again, the graph 504 depicting the residual image shell error (once again magnified by a factor 1000) is a polynomial of degree 4. In the present case, it is a polynomial of degree 4 with a term of degree 4, only.

It is noted that FIGS. 8a and 8b merely show a diameter variation to a constant offset diameter. Furthermore, all units are given in μm.

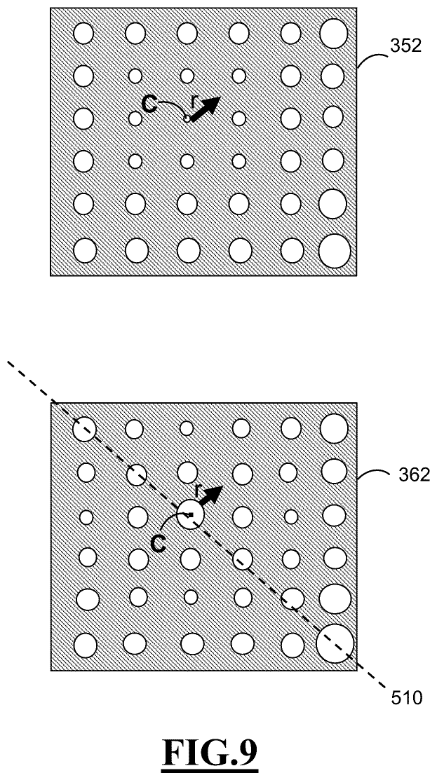

FIG. 9 schematically depicts multi-aperture plates 352, 362 with varying aperture diameters. In more detail, the multi-aperture plate 352 is the second multi-aperture plate of the first multi-lens array 350 applied for a long range focal length variation. The diameter variation is adapted to pre-compensate a spherically curved image shell in the object plane. In the example shown, the diameters of the apertures of the multi-aperture plate 352 vary according to r² to the centre indicated as C. The second multi-aperture plate 352 therefore encodes as a monolithic electrode a parabolic term for field curvature correction.

In contrast thereto, the second multi-aperture plate 362 of the second multi-lens array 360 encodes a residual image shell error correction of third order: the variation of the diameters in plate 362 corresponds to a polynomial of degree 4 and therefore comprises terms of r⁴ and, in the depicted example, also terms of r². This dependency of r can be understood for example when analysing the diameter variation along the line 510. Along the line 510, the diameters increase and decrease, the diameters do not just increase. The embodiment depicted in FIG. 9 shows that a field curvature correction up to the third order can be achieved comparatively easily with only two micro-Einzel-lens arrays specifically encoding diameter variations. It is not necessary to provide a whole series, for example a whole Taylor series to achieve a third order correction of a field curvature.

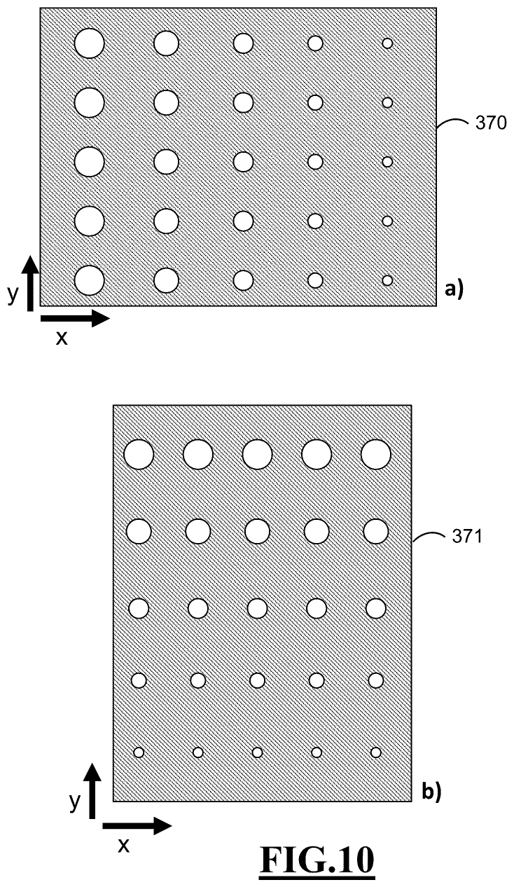

FIGS. 10a, b schematically depict multi-aperture plates 370, 371 of tilt compensation multi-lens arrays. A tilt compensation multi-lens array is suited to compensate an image field inclination in the object plane which can occur for several reasons, for example due to an asymmetric beam-splitter design or simply to a slightly inclined wafer surface. A tilt compensation multi-lens array can comprise a micro-Einzel-lens array. So basically, there are three multi-aperture plates, wherein the first and third multi-aperture plate are connected during use to ground potential and in-between there is a second multi-aperture plate which is connected during use to a specific driving voltage, for example to a first tilt driving voltage. An example of such a second multi-aperture plate 370 comprising a plurality of second apertures is depicted in FIG. 10a. The diameters of the second apertures vary as a linear function f(x) of a position of the respective aperture in direction x, the direction x being perpendicular to the optical axis Z. In other words, the diameters of the second apertures of the multi-aperture plate 370 are comparatively large on the left-hand side and get smaller to the right-hand side, wherein the function describing this variation is linear. During use a first tilt driving voltage is connected to the second multi-aperture plate 370 and the controller 10 or a respective control unit of a controller 10 is configured to provide the first tilt driving voltage to the first tilt compensation multi-lens array for example based on the working point of the multi-beam particle microscope 1. It is possible that a field inclination varies according to the working point of the multi-beam particle microscope. However, it is also possible that the pre-compensated tilt is provided in order to compensate a tilted position of the probe or object, for example a wafer surface which is not 100% orthogonal to the optical axis Z of the system in the object plane. This tilt can stay the same, even if a working point of the multi-beam particle microscope changes.

FIG. 10b schematically illustrates a second multi-aperture plate 371 of a second tilt compensation multi-lens array. During use a second tilt driving voltage is provided to the second multi-aperture plate 371. Whereas the plate 370 allows for a tilt compensation in x-direction, the multi-aperture plate 371 allows for a tilt compensation in y-direction. Once again, the diameters of the second apertures in the plate 371 vary as a linear function, but now according to a linear function of a position of the respective apertures in a direction y. Optionally, the directions x and y are perpendicular to one another and both of them are orthogonal to the optical axis Z. However, in general, it is also possible that the directions x and y are just chosen to be linear independent from one another.

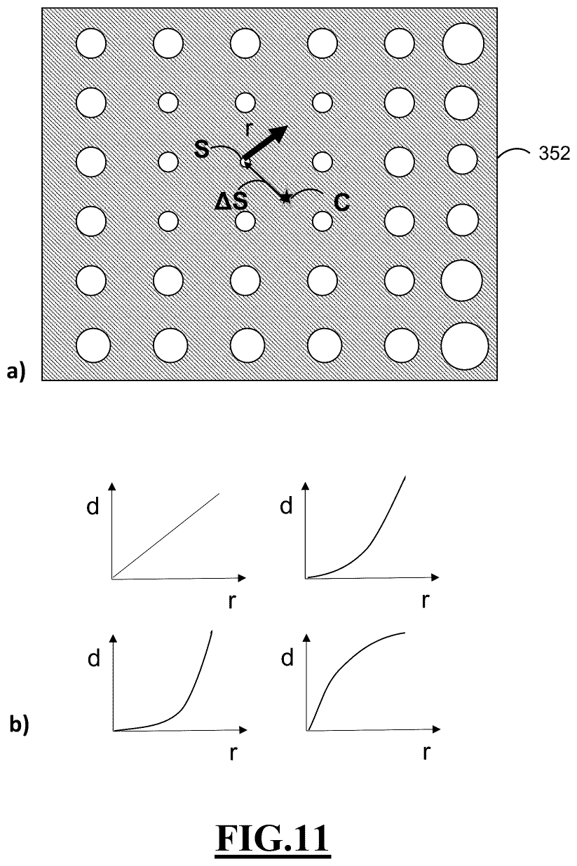

Concerning a tilt compensation, it has to be born in mind that a tilt compensation with just one multi-aperture plate encoded with a linear cartesian coordinate is only suited to compensate a tilt into one direction, for example to the right-hand side. However, with respect to the same coordinate, the tilt can also be provided into the other direction. Therefore, in order to be able to compensate a field inclination or tilt into an arbitrary direction, there is also a third tilt compensation multi-lens array and a fourth tilt compensation multi-lens array, allowing a tilt compensation in a direction (−x) as well in a direction (−y). An overall tilt compensation unit can for example be built up of a sequence of four micro-Einzel-lens arrays comprising the first, the second, the third and the fourth tilt compensation multi-lens array as described above. If it is already known from the very beginning that a field inclination will occur in the multi-beam particle microscope, for example due to an asymmetric beam splitter design, it is also possible to pre-compensate a respective image plane tilt by encoding the pre-compensation already in the first multi-lens array forming the basic part for the long range focal length variation. FIGS. 11a, b schematically depict a respective example: the second multi-aperture plate 352 of the first multi-lens array 350 comprises a plurality of second apertures, wherein the second plurality of apertures have diameters that vary according to a first function of the distance of the respective second aperture of the optical axis Z of the multi-beam particle microscope, but with an additional shift ΔS. If, as shown in the example in FIG. 11a, a parabolic shape for pre-compensating an image curvature is encoded within a multi-aperture plate 352, a vertex S is shifted from a centre C to a position S. With respect to this zenith position S the radial dependency is as previously described with respect to FIG. 7a. Reference is once again also made to FIG. 3 of the present patent application. If a spherical image shell is additionally tilted, a centre 43 will become arranged off-axis from the particle optical axis Z of the system 1.

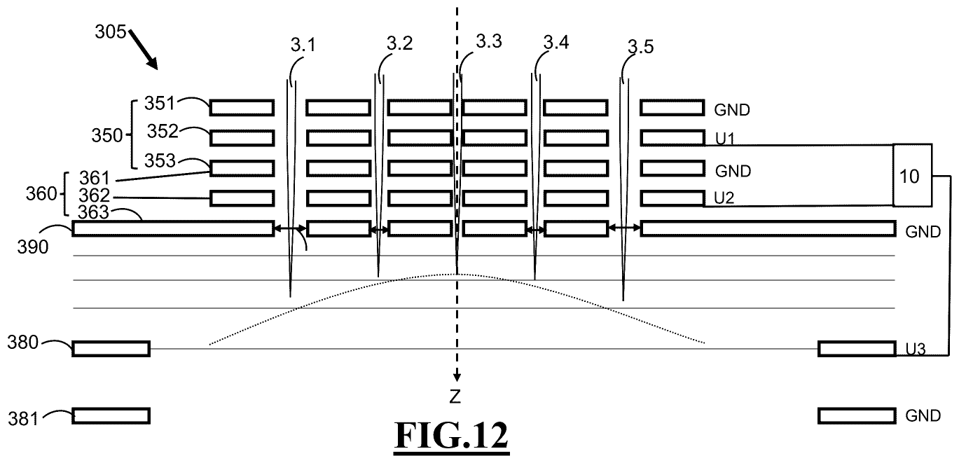

FIG. 12 schematically depicts another multi-beam generator 305 according to the present disclosure. Basically, the multi-beam generator 305 comprises a first multi-lens array 350 for long range focal length variation and a second multi-lens array 360 for short range focal length variation. The second multi-aperture plate 352 is provided with a first driving voltage U1 and the fifth multi-aperture plate 362 is provided with a second driving voltage U2. The other multi-aperture plates 351, 353 (corresponding at the same time to 361) and 363 are connected during use to ground potential. The second multi-aperture plate 352 comprises apertures with varying diameters, so does the fifth multi-aperture plate 362, as previously described. Therefore, basically, once again, the first micro-Einzel lens array 350 encodes a pre-compensation of a spherically curved image shell in the object plane 101 and the second micro-Einzel lens array 360 encodes a correction of a residual image shell error in the object plane.

However, according to the embodiment depicted in FIG. 12, the sixth multi-aperture plate 363 which is connected during use to ground potential, serves at the same time as a terminating multi-aperture plate 390. The terminating multi-aperture plate 390 is defined as the very last multi-aperture plate within the sequence of multi-aperture plates of the multi-beam generator 305. Following the terminating multi-aperture plate 390 an electrode aperture plate 380 with a single opening through which all first individual particle beams 3 pass is provided. This electrode aperture plate 380 is connected during use to an extraction voltage U3. The controller 10 or a respective control unit of the controller 10 is configured to provide the extraction voltage U3 to the electrode aperture plate 380 based on the working point of the multi-beam particle microscope 1, thereby varying an extraction field and thus an immersion lens effect contributing to the focal length variation. The electric field of the immersion lens comprising the ground electrode 390 and the electrode aperture plate 380 differs for the individual particle beams 3.1 to 3.5. This is due to the fact that the electric field leaks or enters to a smaller or larger extent into the apertures of the terminating multi-aperture plate 390 depending on the diameters of the respective apertures. Therefore, by encoding a pattern of certain diameters into the terminating multi-aperture plate 390 and by appropriately controlling the extraction voltage U3 of the electrode aperture plate 380 a further possibility for a focal length variation can be provided.

It is noted that the multi-beam generator 305 depicted in FIG. 12 can comprise further elements or features not specifically illustrated in FIG. 12.

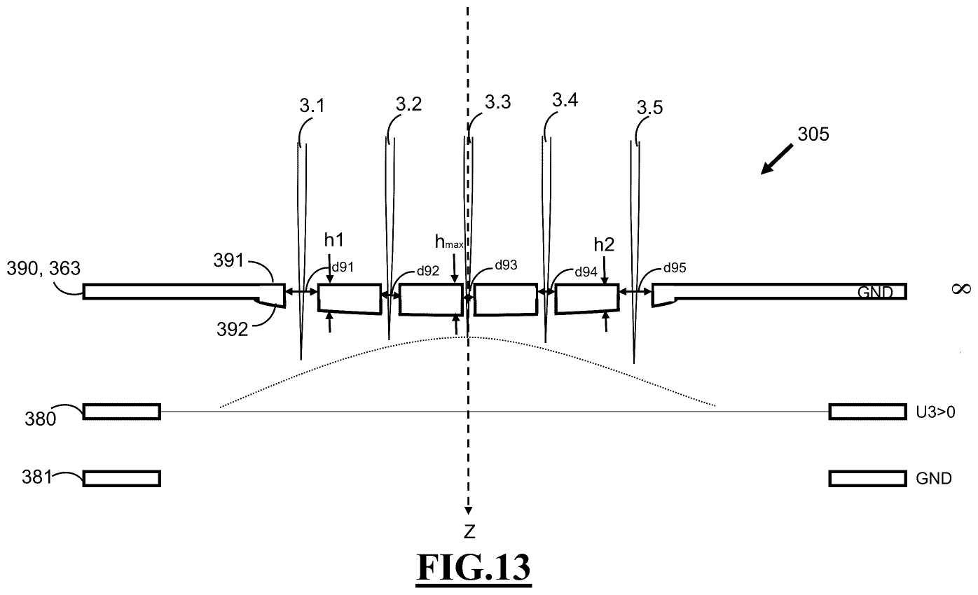

FIG. 13 schematically depicts a terminating multi-aperture plate 390 with varying shape. This terminating multi-aperture plate 390 can be the sixth multi-aperture plate 363 of the second multi-lens array 360, but in general it can be another multi-aperture plate provided at the terminating position and therefore as the last multi-aperture plate within the multi-beam generator 305. Once again, the terminating multi-aperture plate 390 and the electrode aperture plate 380 with a single central opening are combined to form an immersion lens. According to the depicted embodiment, the terminating multi-aperture plate 390 comprises a plurality of terminating apertures with varying diameters d91 to d95. The diameters d91 to d95 vary as a function of the distance r of the respective aperture from the optical axis Z. Furthermore, the terminating multi-aperture plate 390 has an upper surface 391 which is plane and a bottom surface 392 which is shaped convex with respect to the direction of a particle optical beam path. Therefore, the terminating multi-aperture plate 390 has a maximum thickness hₘₐₓ in the vicinity of the middle opening with the diameter d93 through which the third individual particle beams 3.3 passes. The thickness of the plate 390 is reduced further away from the particle optical axis Z, the hights h1 and h2 are smaller than the hight hₘₐₓ. It has turned out that varying the shape of the terminating multi-aperture plate 390, more specifically its thickness h, can further contribute to a variation of the immersion lens effect per individual particle beam 3.1 to 3.5. It is therefore possible to encode another possibility in the terminating multi-aperture plate 390 for an individual focal length variation per beam.

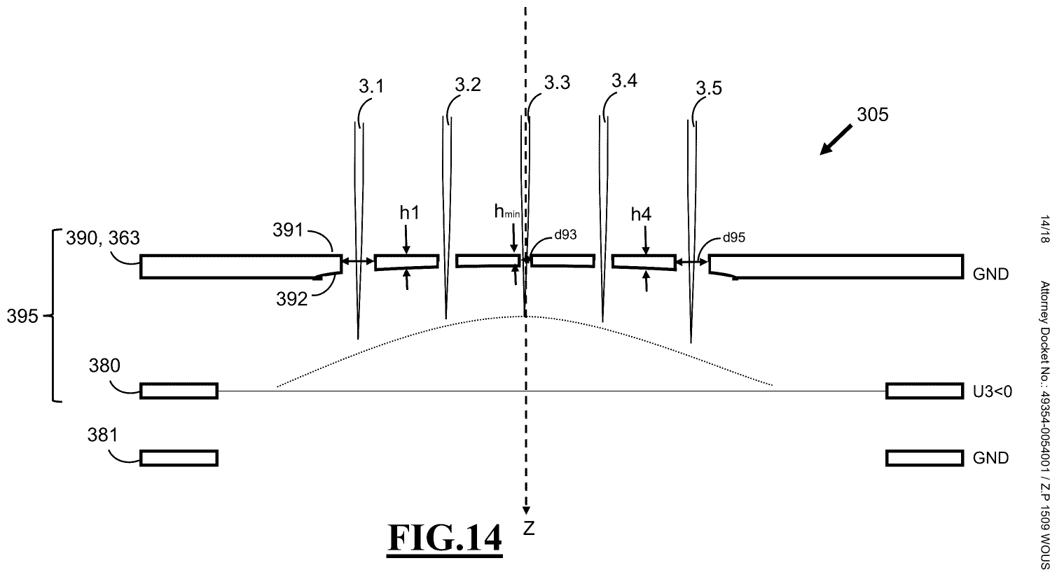

FIG. 14 schematically depicts another terminating multi-aperture plate 390 with varying shape. In comparison to the embodiment depicted in FIG. 13, the shape of the bottom surface 392 is different: the bottom surface 392 is shaped concave with respect to the direction of the particle optical beam path. Therefore, the thickness of the terminating multi-aperture plate 390 is minimum at the centre aperture through which particle beam 3.3 passes in the depicted example. The minimum thickness is indicated as hₘᵢₙ. With increasing distance from the particle optical axis Z the thickness increases to h3 and h4, for example. The diameter variation of the apertures in FIG. 14 itself is the same as in FIG. 13.

Depending on the shape of the bottom surface 392 the sign of the extraction voltage is adapted. In combination with a convex shape of the bottom surface 392 of the terminating multi-aperture plate 390 the extraction voltage is negative (in case of electrons or other negatively charged particles providing the individual particle beams). In combination with a concave bottom surface 392 the extraction voltage U3 provided at the electrode aperture plate 380 is positive (in case of electrons or other negatively charged particles providing the individual particle beams). It is noted that in general also other shapes of the terminating multi-aperture plate 390 and for example of the bottom surface 392 are possible, for example a stepped shape or partly linearly varying shape.

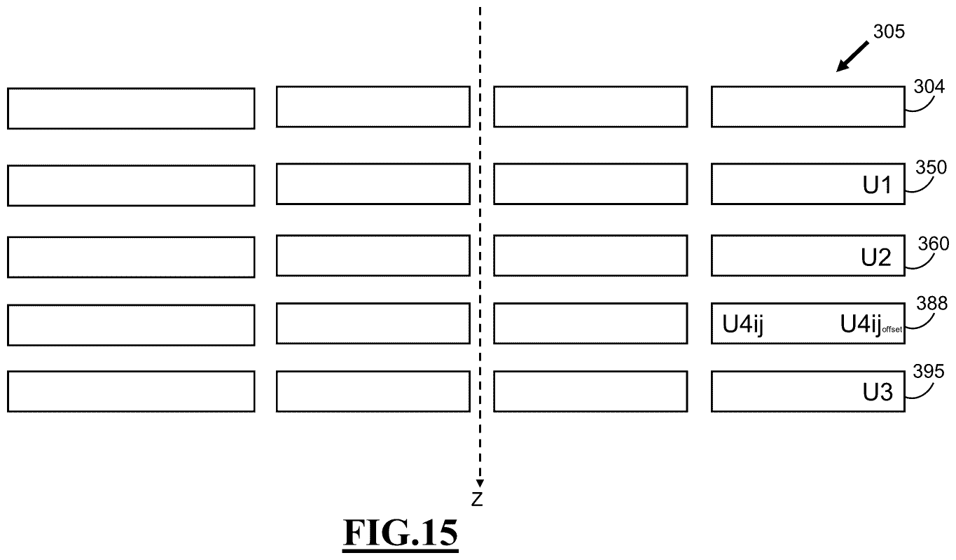

FIGS. 15 to 17 schematically depict other embodiments of the multi-beam generator 305 according to the present disclosure. FIGS. 15 to 17 are not true to scale and they do also not explicitly show the diameter variation of certain multi-aperture plates as described above in further details. Instead, the main aspect depicted in FIGS. 15 to 17 is the combination of modules or multi-lens arrays forming the multi-beam generator 305.

The multi-beam generator 305 depicted in FIG. 15 comprises the following elements or units in the following order: at the very beginning, a filter plate 304 is provided, comprising a plurality of filter apertures for generating the plurality of first individual particle beams. The filter plate 304 is connected during use to ground potential.

Following the filter plate 304, a first multi-lens array 350 for long range focal length variation is provided. It comprises a stack of multi-aperture plates forming a micro-Einzel lens array. The middle multi-aperture plate is connected during use to the first driving voltage U1 and the diameter variations in the first multi-lens array encode a pre-compensation of a spherically curved image shell in the object plane.

Subsequently, a second multi-lens array 360 for short range focal length variation is provided. In the embodiment depicted in FIG. 15 the second multi-lens array 360 is realized as another micro-Einzel lens array having a middle multi-aperture plate with a plurality of fifths apertures having diameters that vary according to a second function of the distance of the respective aperture from the optical axis Z, wherein this second function is adapted to pre-compensate the residual image shell error in the object plane which is not pre-compensated by the first multi-lens array 350.

Subsequently, a stigmation multi-aperture plate 388 is provided comprising a plurality of apertures with a plurality of individually addressable electrostatic multi-pole electrodes being arranged in the circumference of each aperture. During use, a set of driving voltages U4ij is provided to each of the multi-pole electrodes adapted for stigmation purposes. Additionally, each set of driving voltages U4ij can comprise an individual offset voltage U4ij_{offset} common to all electrodes of a respective multi-pole electrode based on the working point of the multi-beam particle microscope. This individual offset voltage U4ij_{offset} contributes to a focal length variation which can be adapted individually for each individual particle beam 3.

Subsequently, an immersion lens array 395 is provided comprising a terminating multi-aperture plate 390 connected during use to ground potential as well as an electrode aperture plate 380 with a single opening which is connected during use to an extraction voltage. The immersion lens array 395 can be designed as described with respect to FIGS. 12 to 14, for example.

In general, an order of different correctors within the multi-beam generator 305, for example an order of the multi-lens arrays 350, 360, the tilt-compensation multi-lens arrays 370, 371 and the stigmation multi-aperture plate 388 within the multi-beam generator 305, can be freely chosen. However, it can be advantageous to provide the stigmation multi-aperture plate 388 as the first corrector in the sequence of correctors, because this position might have advantages from an alignment/adjustment perspective.

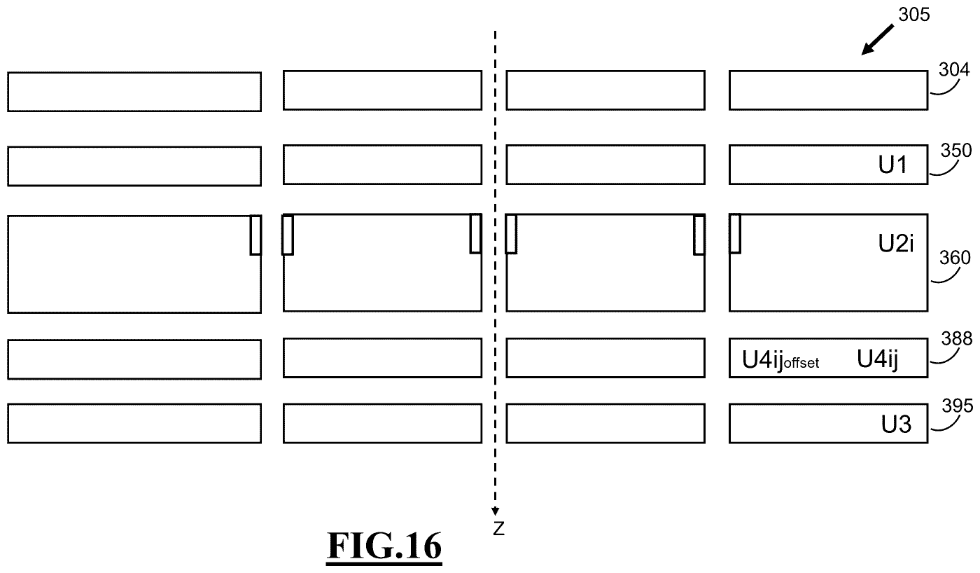

FIG. 16 depicts another multi-beam generator 305 which differs from the multi-beam generator 305 depicted in FIG. 15 with respect to the second multi-lens array 360: in FIG. 16, the second multi-lens array 360 is not geometry encoded but comprises a multi-aperture plate comprising a plurality of apertures with a plurality of individually addressable ring-electrodes being arranged around each aperture. The controller 10 of the multi-beam generator 305 is configured to provide an individual second driving voltage U2i to each of the ring-electrodes based on the working point of the multi-beam particle microscope.

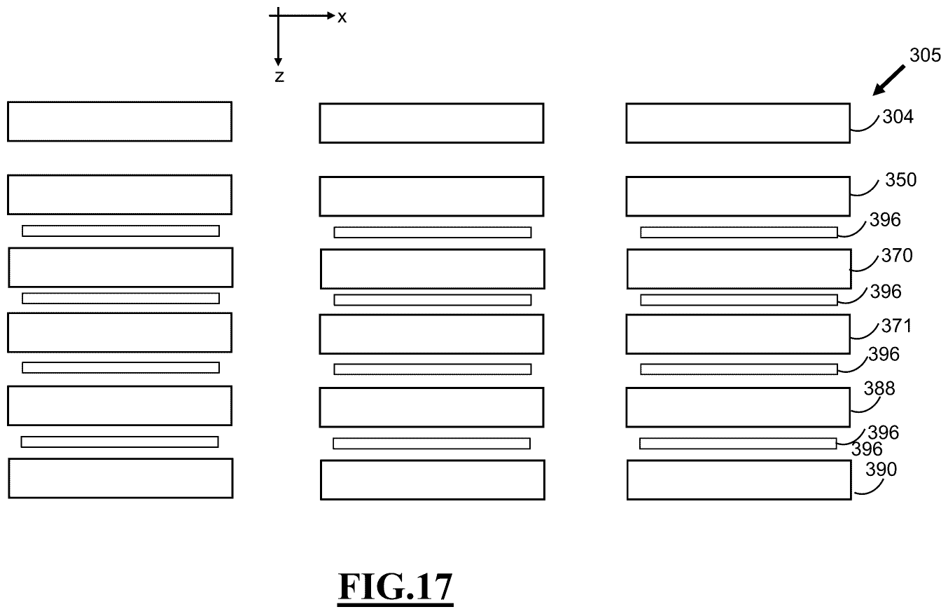

FIG. 17 discloses another sequence of elements of a multi-beam generator 305: first of all, the filter plate 304 is provided. Subsequently, a first multi-lens array 350 for long range focal length variation is provided. In this embodiment, the diameter variation encoded in this micro-lens array 350 is adapted to pre-compensate a spherically curved image shell in the object plane and on top to bias an image plane tilt, for example originating from an asymmetric beam splitter design. This means that the first function describing the diameter variation of the plurality of second apertures in the second multi-aperture plate 352 of the first multi-lens array 350 is not only a function of the distance r from the optical axis Z, but is also a linear function of the position of the respective apertures in a direction −x/and or −y, the directions −x and −y being perpendicular to the optical axis Z and being linear independent, optionally orthogonal, to one another.

Subsequently, a first tilt compensation multi-lens array 370 is provided for compensating a first tilt in x-direction. Subsequently, a second tilt compensation multi-lens array 371 is provided for compensating an image plane tilt in y-direction. This means that in the tilt compensation multi-lens arrays 370, 371 a linear function f(x), f(y) of a position of the respective apertures in a direction x or in a direction y, respectively is encoded.

Subsequently to the tilt compensation multi-lens arrays 370, 371, a stigmation multi-aperture plate 388 is provided as previously explained with respect to FIGS. 15 and 16. Subsequently, a terminating multi-aperture plate 390 set to ground potential is provided. It is of course possible that further elements are comprised in the multi-beam generator 305, for example an immersion lens array 395.

Optionally, shielding layers 396 can be provided between subsequent multi-lens arrays.

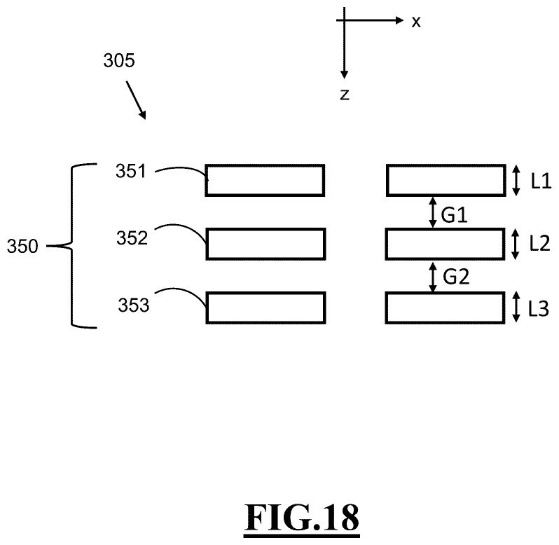

FIG. 18 schematically illustrates dimensions of a multi-lens array. FIG. 18 is not true to scale. Further investigations of the inventors have shown that a focal length variation can be further increased by optimizing plate dimensions, for example plate dimensions of the first multi-lens array 350 which is applied for the long range focal length variation. The biggest field curvature correction potential can be realized for the shortest electrode length L2 of the second multi-aperture plate 352, the smallest gaps G1, G2 between the first and second multi-aperture plate 351, 352 as well as between the second and third multi-aperture plate 352, 353 of the first micro-lens array 350 and by using counter-electrodes 351, 353 of the Einzel-lens systems with smallest thickness L1, L3.

According to an embodiment, the following relation holds for a thickness L2 of the second multi-aperture plate 352 of the first multi-lens array 352: L2≤50 μm, optionally L2≤30 μm.

According to an embodiment, the following relation holds for a thickness L1 of the first multi-aperture plate of the first multi-lens array: L1≥80 μm, optionally L1≥100 μm.

Additionally or alternatively, the following relation holds for a thickness L3 of the third multi-aperture plate 353 of the first multi-lens array 350: L3≥80 μm, optionally L3≥100 μm.

According to an embodiment, the following relation holds for a gap G1 between the first multi-aperture plate 351 and the second multi-aperture plate 352 of the first multi-lens array 350: G1≤10 μm, optionally G1≤5 μm. Additionally or alternatively, the following relation holds for a gap G2 between the second multi-aperture plate 352 and the third multi-aperture plate 353 of the first multi-lens array 350: G2≤10 μm, optionally G2≤5 μm.

In general, the above findings concerning the dimensions of the Einzel-lens array 350 can be transferred to other multi-lens arrays as well.

According to an embodiment, a multi-beam generator 305 for a charged-particle multi-beam system 1 is provided, comprising a stack of multi-aperture plates with at least a first multi-lens array 350 for long range focal length variation and a second multi-lens array 360 for short range focal length variation. Aperture diameters of the first multi-lens array 350 vary to encode a pre-compensation of a spherically curved image field in an object plane of the multi-beam system 1. Aperture diameters of the second multi-lens array 360 vary to encode a pre-compensation of a residual image field error in the object plane which is not pre-compensated by the first multi-lens array 350. The control unit 10 of the multi-beam generator 305 provides driving voltages U1, U2 to the first and second lens arrays 350, 360 based on the current working point of the charged-particle multi-beam system 1.

The above-described embodiments are not to meant to be limiting to the present disclosure. Instead, they shall only represent exemplary embodiments.

It is noted that U.S. Pat. No. 11,322,335 B2 proposes a quadratic dependence of the aperture diameters in a multi-aperture array for field curvature compensation. Especially with a purely quadratic dependence of the aperture diameters once fixed, another aperture plate with variable aperture diameters with a spatial dependence of 4^{th} order or even higher order is used. This is illustrated in FIG. 8b of the present patent application. However, with larger image fields with more individual particle beams of, for example, more than 90, more than 300 or even more individual particle beams, an image shell error becomes larger and larger and a limitation to a quadratic function in a multi-aperture plate is no longer sufficient for a correction. For a correction at a selected working point or setting point of the multi-beam particle microscope, the radial dependence of the aperture diameters in a multi-aperture plate is designed according to the following criteria:

(a) The spatial course of the focal points follow the image shell. A portion of the image shell can be determined in a mathematically simple way, for example, by a root function or a cosine function of the angle with respect to a symmetry axis. This spherical portion of the image shell is deformed by the spatially invariant focus effect of the deceleration field. Altogether this results in a power series of the focal length f as a function of the distance r from a symmetry axis with f(r)˜f0+ΣᵢAi rⁱ, with coefficients Ai, where besides the first, quadratic order at least one higher, fourth order is considered. For larger image fields with even more individual particle beams of, for example, more than 90, more than 300 or even more individual particle beams, further orders, such as the sixth order and even higher orders, can be considered.

(b) The achieved focal length change behaves only approximately linear to the change of an aperture diameter of a multi-aperture plate. In an example of the aperture diameter design described here, this nonlinearity is taken into account.

Even with an ideal design of a multi-aperture plate for a working point or setting of the multi-beam particle microscope, however, an issue can remain that the image shell changes with a change of working point or setting.

### Example 1: Multibeam System Comprising

a first multi-aperture plate with apertures of variable diameters, designed for a field curvature or image shell correction at a selected working point or setting point under consideration of criteria (a) and (b);
a second aperture plate with apertures of variable diameters, designed for a field curvature or image shell correction at working points or setting points deviating from the selected working point or setting point.

### LIST OF REFERENCE SIGNS

1 Multi-beam particle microscope
3 Primary particle beams (individual particle beams)
5 Beam spots, incidence locations
7 Object
9 Secondary particle beams
10 Computer system, controller
15 Sample surface, wafer surface
25 secondary charged particle image spot
41 y-axis through the position of the axial primary beam
43 centre
45 tilted image plane
47 lower focal plane
49 upper focal plane
50 image shell
51 z-extent or interval
53 approximately concentric rings or hexagons with focal points with a similar resolution
55 spot
57 rejected primary beams not meeting a resolution criterion
60 optical axis
62 beam cone of a primary beam in the vicinity of a focal plane
74 minimal spot extent
79 ring-shaped electrodes
81 multi-pole electrode
82 annular electrode
83 spacers
85 apertures
86 spacer
99 absorbing and conductive layer
101 Object plane
102 Objective lens
105 optical axis of multi-beam charged particle microscope
200 Detector system
205 Projection lens system
206 electrostatic lens
207 Particle multi-detector
208 projection lens
209 projection lens
210 projection lens
212 Cross-over
214 Aperture filter
218 Deflector system
220 Multi-aperture corrector, individual deflector array
222 Collective deflection system, anti-scan
300 Beam generating apparatus
301 Particle source, beam generating system
303 Collimation lens system
304 multi-aperture array, filter plate
305 Multi-aperture arrangement, multi-beam generator
306 Micro-optics
307 Field lens
308 Field lens
309 Particle beam
321 Intermediate image plane
323 Beam foci
333 support zone
335 membrane zone
350 first multi-lens array for long range focal length variation
351 first multi-aperture plate
352 second multi-aperture plate
353 third multi-aperture plate
360 second multi-lens array for short range focal length variation
361 first multi-aperture plate
362 second multi-aperture plate
363 third multi-aperture plate
370 multi-aperture plates of tilt compensation multi-lens array
371 multi-aperture plates of tilt compensation multi-lens array
380 electrode aperture plate
381 single aperture plate
388 stigmation multi-aperture plate, multi-stigmator
390 terminating multi-aperture plate
391 top surface
392 bottom surface
395 immersion lens array
396 shielding layer
400 Beam switch
500 Collective scan deflector
501 image shell
502 image shell
503 residual image shell error
504 residual image shell error
510 line
550 box
600 Sample stage
d diameter of aperture
h height/thickness of multi-aperture plate
R radius
M middle point or centre
C centre
S vertex
ΔS shift
Z optical axis
Δz focal length variation
G1 gap
G2 gap
L1 thickness
L2 thickness
L3 thickness

1. A multi-beam charged particle microscope, comprising:
a multi-beam generator configured to generate a multiplicity of charged first individual particle beams defining a first field;
a first particle optical unit having a first particle optical beam path, the first particle optical unit configured to image the first individual particle beams onto an object in an object plane so that the first individual particle beams impinge on a surface of the object at incidence locations defining a second field;
a detection system comprising a multiplicity of detection regions defining a third field;
a second particle optical unit with a second particle optical beam path, the second particle optical unit configured to image second individual particle beams emanating from the incidence locations in the second field onto the third field;
a magnetic and/or electrostatic objective lens configured so that the first and the second individual particle beams pass therethrough;
a beam switch in the first particle optical beam path between the multi-beam particle generator and the objective lens, the beam switch in the second particle optical beam path between the objective lens and the detection system;
a sample stage configured to hold and/or position the object; and
a controller;
wherein:
the multi-beam charged particle microscope is configured to operate at a plurality of working points so that the first particle optical unit generates a plurality of spherically curved image fields in the object plane, the spherically curved image fields being pre-compensated by the multi-beam generator;
the multi-beam generator comprises:
i) a filter plate comprising a plurality of filter apertures configured to generate the plurality of first individual particle beams, the filter plate connected to ground potential during use; and
ii) a stack of multi-aperture plates comprising a first multi-lens array for long range focal length variation, the first multi-lens array comprising:
a) a first multi-aperture plate comprising a plurality of first apertures, the first multi-aperture plate configured to be connected to ground potential during use;
b) a second multi-aperture plate comprising a plurality of second apertures, the second multi-aperture plate configured to be connected to a first driving voltage during use, the second plurality of apertures having diameters that vary according to a first function of a distance of the respective second aperture from an optical axis of the multi-beam particle microscope, the first function configured to a pre-compensate a spherically curved image shell in the object plane; and
c) a third multi-aperture plate comprising a plurality of third apertures, the third multi-aperture plate configured to be connected to ground potential during use, the first, the second and the third apertures aligned with one another; and
iii) a second multi-lens array for short range focal length variation, the second multi-lens array aligned with the first multi-lens array, the second multi-lens array configured to pre-compensate a residual image shell error in the object plane which is not pre-compensated by the first multi-lens array;
the controller is configured to provide a first driving voltage to the first multi-lens array based on the working point of the multi-beam particle microscope; and
the controller is configured to provide a second driving voltage to the second multi-lens array based on the working point of the multi-beam particle microscope.

2. The multi-beam particle microscope of claim 1, wherein:
the diameter variation of the second apertures according to the first function in the second multi-aperture plate is optimum for pre-compensating during use for a spherically curved image shell in the object plane at a pre-selected reference working point;
the controller is configured to provide a first driving voltage to the first multi-lens array at a reference working point which is not zero; and
the controller is configured to provide a second driving voltage to the second multi-lens array at a reference working point which is zero.

3. The multi-beam particle microscope of claim 2, wherein the controller is configured to provide:
a first driving voltage to the first multi-lens array at a second working point which is different from the first driving voltage provided at the reference working point which is not zero; and
a second driving voltage to the second multi-lens array at the second working point which is not zero.

4. The multi-beam particle microscope of claim 1, wherein the second multi-lens array comprises:
a fourth multi-aperture plate comprising a plurality of fourth apertures, the fourth multi-aperture plate configured to be connected to ground potential during use;
a fifth multi-aperture plate comprising a plurality of fifth apertures, the fifth multi-aperture plate configured to be connected to a second driving voltage during use, the plurality of fifth apertures having diameters that vary according to a second function of the distance of the respective aperture from the optical axis of the multi-beam particle microscope, the second function being configured to pre-compensate the residual image shell error in the object plane which is not pre-compensated by the first-multi-lens array; and
a sixth multi-aperture plate comprising a plurality of sixth apertures, the sixth multi-aperture plate configured to be connected to ground potential during use, and
wherein:
centers of the fourth, the fifth and the sixth apertures are aligned with one another; and
the controller is configured to control the second driving voltage based on the working point of the multi-beam particle microscope.

5. The multi-beam particle microscope of claim 4, wherein:
the third multi-aperture plate of the first multi-lens array and the fourth multi-aperture plate of the second multi-lens array are the same multi-aperture plate; or
the first multi-aperture plate of the first multi-aperture plate and the sixth multi-aperture plate of the second multi-lens array are the same multi-aperture plate.

6. (canceled)

7. (canceled)

8. The multi-beam particle microscope of claim 1, wherein the first function is a polynomial of degree n with n∈ [symbol] and n≥2.

9. The multi-beam particle microscope of claim 1, wherein:
the second multi-lens array comprises a multi-aperture plate comprising a plurality of apertures with a plurality of individually addressable ring-electrodes being around each aperture; and
the controller is configured to provide an individual second driving voltage to each of the ring-electrodes based on the working point of the multi-beam particle microscope.

10. (canceled)

11. The multi-beam particle microscope of claim 1, wherein the first driving voltage is less than 150 Volts (V), or the first driving voltage is at least 200 V and at most 400 V.

12. The multi-beam particle microscope of claim 1, wherein, for all working points, a ratio of a focal length variation achieved with the first multi-lens array only to an overall achieved focal length variation within the image field in the object plane is at least 0.80.

13. The multi-beam particle microscope of claim 1, wherein the multi-beam particle microscope is configured to pre-compensate a focal length variation within the image field in the object plane of least one micrometer.

14. The multi-beam particle microscope of claim 1, wherein the multi-beam generator comprises a further multi-lens array configured to contribute to pre-compensation of the focal length variation within the image field in the object plane.

15. The multi-beam particle microscope of claim 14, further comprising a first tilt compensation multi-lens array, the tilt compensation multi-lens array comprising:
a first multi-aperture plate comprising a plurality of first apertures, the first multi-aperture plate configured to be connected to ground potential during use;
a second multi-aperture plate comprising a plurality of second apertures, the second multi-aperture plate configured to be connected to a first tilt driving voltage during use, diameters of the second apertures vary as a basically linear function of a position of the respective aperture in a first direction which is perpendicular to the optical axis;
a third multi-aperture plate comprising a plurality of third apertures, the third multi-aperture plate configured to be connected to ground potential during use, centers of the first, the second and the third apertures aligned with one another,
wherein the controller is configured to provide the first tilt driving voltage to the first tilt compensation multi-lens array.

16. The multi-beam particle microscope of claim 15, further comprising a second tilt compensation multi-lens array, the second tilt compensation multi-lens array comprising:
a first multi-aperture plate comprising a plurality of first apertures, the first multi-aperture plate configured to be connected to ground potential during use;
a second multi-aperture plate comprising a plurality of second apertures, the second multi-aperture plate configured to be connected to a second tilt driving voltage during use, diameters of the second apertures varying as a basically linear function of a position of the respective aperture in a second direction which is perpendicular to the optical axis Z and linearly independent from the first direction;
a third multi-aperture plate comprising a plurality of third apertures, the third multi-aperture plate configured to be connected to ground potential during use, centers of the pluralities of the first, the second and the third apertures aligned with one another,
wherein the controller is configured to provide the second tilt driving voltage to the second tilt compensation multi-lens array.

17. The multi-beam particle microscope of claim 1, wherein the first function describing the diameter variation of the plurality of second apertures in the second multi-aperture plate of the first multi-lens array is also a linear function of a position of the respective apertures in a first direction and/or a second direction, the first and second directions being perpendicular to the optical axis and being linear independent, and wherein the linear function of the first direction and/or second direction is adapted to bias a field inclination in the object plane.

18. The multi-beam particle microscope of claim 1, further comprising a stigmation multi-aperture plate comprising a plurality of apertures comprising a plurality of individually addressable electrostatic multi-pole electrodes being arranged in the circumference of each aperture,
wherein the controller is configured to provide a set of driving voltages to each of the multi-pole electrodes, each set of driving voltage comprising an individual offset voltage common to all electrodes of a respective multi-pole electrode based on the working point of the multi-beam particle microscope.

19. The multi-beam particle microscope of claim 1, wherein the multi-beam generator comprises in this order:
a terminating multi-aperture plate comprising a plurality of terminating apertures, a diameter of the terminating apertures varying as a function of a distance of the respective aperture from the optical axis, the terminating multi-aperture plate being configured to be connected to ground potential during use; and
an electrode aperture plate comprising a single opening configured so that each first individual particle beam passes therethrough, the electrode aperture plate configured to be connected to an extraction voltage during use,
wherein centers of the terminating multi-aperture plate and the electrode aperture plate are aligned with one another, and
wherein the controller is configured to provide the extraction voltage to the electrode aperture plate based on the working point of the multi-beam particle microscope to vary an extraction field and an immersion lens effect contributing to the focal length variation.

20.-23. (canceled)

24. The multi-beam particle microscope of claim 1, wherein:
a gap between the first and second multi-aperture plates of the first multi-lens array is at most 10 microns; and/or
a gap between the second and third multi-aperture plates of the first multi-lens array is at least 10 microns.

25. The multi-beam particle microscope of claim 1, further comprising a mechanism configured to generate a voltage gradient on the second multi-aperture plate of the first multi-lens array, wherein the controller is configured to provide a gradient driving voltage to the second multi-aperture plate to pre-compensate a field inclination in the object plane.

26.-28. (canceled)

29. A multi-beam generator, comprising:
i) a filter plate comprising a plurality of filter apertures configured to generate a plurality of first individual particle beams, the filter plate configured to be connected to ground potential during use;
ii) a stack of multi-aperture plates comprising a first multi-lens array for long range focal length variation, the first multi-lens array comprising:
a) a first multi-aperture plate comprising a plurality of first apertures, the first multi-aperture plate configured to be connected to ground potential during use,
b) a second multi-aperture plate comprising a plurality of second apertures, the second multi-aperture plate configured to be connected to a first driving potential during use, the second plurality of apertures having diameters that vary according to a first function of the distance of the respective second aperture from the optical axis of the multi-beam system, the first function being adapted to pre-compensate a spherically curved image field in an object plane of the multi-beam system; and
c) a third multi-aperture plate comprising a plurality of third apertures, the third multi-aperture plate configured to be connected to ground potential during use, centers of the first, the second and the third apertures aligned with one another;
iii) a second multi-lens array for short range focal length variation, the second multi-lens array aligned with the first multi-lens array, and the second multi-lens array configured to pre-compensate a residual image field error in the object plane which is not pre-compensated by the first multi-lens array; and
a control unit configured to provide a first driving voltage to the first multi-lens array based on a working point of the multi-beam system, the control unit is configured to provide a second driving voltage to the second multi-lens array based on the working point of the multi-beam system.

30. A multi-beam charged particle microscope comprising the multi-beam generator of claim 29.
